(19) United States
(12) Patent Application Publication
(10) Pub. No.: US 2012/0152758 A1
(43) Pub. Date: Jun. 21, 2012

(54) METHOD FOR PROCESSING OF GLASS, PROCESS FOR PRODUCTION OF WIRING SUBSTRATE, PROCESS FOR PRODUCTION OF MICROCHIP, AND PROCESS FOR PRODUCTION OF MICROLENS ARRAY SUBSTRATE

(75) Inventors: Kazuya Tsujino, Osaka-shi (JP); Michio Matsumura, Toyonaka-shi (JP)

(73) Assignee: SHARP KABUSHIKI KAISHA, Osaka (JP)

(21) Appl. No.: 13/388,977

(22) PCT Filed: Mar. 24, 2010
(86) PCT No.: PCT/JP2010/002080

§ 371 Date: Mar. 12, 2012

(30) Foreign Application Priority Data
Aug. 6, 2009 (JP) 2009-183727

(51) Int. Cl. H05K 3/00; C25F 3/14

(52) U.S. Cl. 205/674; 29/848

(57) ABSTRACT

Provided is a method for processing glass, which can process glass with fewer steps and thus at less cost than of the conventional methods. In the present processing method, a part of a glass substrate (6) is locally dissolved, which part is located in the vicinity of a processing electrode (1), by causing the processing electrode (1), that acts as an anode, to be in contact with or in proximity to the glass substrate (6) in a processing liquid (8), the processing liquid containing fluoride ions, water, and an acid-generating assistant agent which is more easily oxidized than water and generates hydrogen ions upon being oxidized.

### TECHNICAL FIELD

The present invention relates to method for processing glass by wet etching to form at least one opening or groove therein, and methods for manufacturing a wiring board, a microchip and a microlens array substrate, with the use of the method for processing glass.

### BACKGROUND ART

Glass is widely used in a variety of products including a glass substrate in a liquid crystal or plasma display device, an ink-jet head in an ink-jet printer, a wiring board, optical components of a microarray substrate, a microchip for a chemical analysis, and a microelectromechanical system (MEMS).

The manufacturing of those products requires processing of glass, such as cutting of glass, and forming of at least one groove, through-hole or recess in a glass substrate (see, for example, Patent Literatures 1 to 11).

For example, Patent Literature 1 discloses an approach of forming grooves for buried wires in a glass substrate.

Patent Literature 2 discloses a method for inexpensively manufacturing partition walls for a plasma display device, in which grooves are formed in a glass substrate.

Patent Literature 3 discloses a method for manufacturing an ink-jet head in which grooves are formed in glass.

Patent Literature 4 discloses a method for forming through-holes in a glass substrate of a plasma display device in which through electrodes are formed in the through-holes. The through electrodes are used as electrode terminals.

Patent Literature 5 proposes a microlens array substrate manufactured by a method including the step of forming recesses in glass.

Patent Literature 6 discloses a method for manufacturing a microchemical chip in which grooves and depressions are formed in glass.

Patent Literature 7 proposes a method for forming a hole in a glass substrate used in a microelectromechanical system (MEMS), the hole being for electrically connecting components.

Patent Literature 8 discloses a method for manufacturing a glass substrate on which through electrodes are formed. In the method, through holes are formed in the glass substrate.

Patent Literatures 9 to 11 teach that through-holes are formed in a counter substrate or a TFT substrate of a liquid crystal panel and through electrodes are formed in the substrates.

To form an opening or a groove in glass, mechanical processing or laser processing is generally used. However, the physical processing methods with the use of (i) a drill or a water jet as disclosed in Patent Literature 4 and (ii) sandblast etching as disclosed in Patent Literature 7, may cause glass to be mechanically damaged so that small cracks or chippage around the chipped portions occur. Alternatively, the methods may cause glass to be mechanically damaged by overstress generated during the processing.

Although the method with the use of laser irradiation as disclosed in Patent Literature 9 does not mechanically damage glass, the method may thermally damage the glass around regions irradiated with laser.

In contrast, the methods in which wet etching is used, as disclosed in Patent Literatures 1 to 3, are known as one for processing glass without causing mechanical or thermal damage, which may be caused by the above-mentioned processing.

### CITATION LIST

Patent Literature 1
Japanese Patent Application Publication Tokukai No. 2003-66864 (Publication date: Mar. 5, 2003)

Patent Literature 2
Japanese Patent Application Publication Tokukai No. 2003-229048 (Publication date: Aug. 15, 2003)

Patent Literature 3
Japanese Patent Application Publication Tokukai No. 2002-145643 (Publication date: May 22, 2002)

Patent Literature 4
Japanese Patent Application Publication Tokukai No. 2008-34214 (Publication date: Feb. 14, 2008)

Patent Literature 5
Japanese Patent Application Publication Tokukai No. 2009-37257 (Publication date: Feb. 19, 2009)

Patent Literature 6
Japanese Patent Application Publication Tokukai No. 2004-340752 (Publication date: Dec. 2, 2004)

Patent Literature 7
Japanese Patent Application Publication Tokukai No. 2004-160649 (Publication date: Jun. 10, 2004)

Patent Literature 8
Japanese Patent Application Publication Tokukai No. 2006-165137 (Publication date: Jun. 22, 2006)

Patent Literature 9
Japanese Patent Application Publication Tokukai No. 2008-96641 (Publication date: Apr. 24, 2008)

Patent Literature 10
Japanese Patent Application Publication Tokukai No. 2008-275894 (Publication date: Nov. 13, 2008)

Patent Literature 11
Japanese Patent Application Publication Tokukai No. 2007-11030 (Publication date: Jan. 18, 2007)

Patent Literature 12
International Publication WO97/46489 (Publication date: Dec. 11, 1997)

Patent Literature 13
Japanese Patent Application Publication Tokukai No. 2005-218908 (Publication date: Aug. 18, 2005)

Patent Literature 14
Japanese Patent Application Publication Tokukai No. 2005-211780 (Publication date: Aug. 11, 2005)

Non-Patent Literature 1
Tsujino, K. et al, Local wet etching of glass by acidification utilizing electrochemistry. J Micromech Microeng, 2008, 18, 115023.

### SUMMARY OF INVENTION

### Technical Problem

However, the processing of glass employing wet etching requires forming mask patterns by photolithography. It is because an etching solution does not have a function to locally dissolve a predetermined part of a glass surface. Accordingly, a part, which is desired to be undissolved, should be masked when an opening or a groove is formed in glass.

Accordingly, the conventional method for processing a glass substrate, which employs wet etching, has disadvantage in having a large number of steps.

Since the conventional method requires mask patterns, it is difficult to perform fine processing, as is the case with Patent Literatures 4 and 8 in which glass is processed with the use of a mold.

A novel processing method to solve the above-mentioned problems has thus been found by the inventors of the present application and published (see Non-Patent Literature 1), in which glass is processed by etching utilizing local acidification of an etching solution near a platinum wire electrode.

According to the method, glass can easily be processed by using wet etching, without the formation of mask patterns by photolithography. Hence, glass can be processed with fewer steps and thus at less cost than of the conventional methods. In addition, glass can finely be processed due to the disuse of mask patterns.

However, the above-mentioned method uses chemical reactions to process glass and thus has a problem in processing speed. The method is thus susceptible to improvement.

The present invention has been accomplished in view of the above-mentioned problem and one object of the present invention is to provide a novel method for processing glass, which allows to process glass with fewer steps and thus at less cost than of the conventional methods and has excellent processing speed, and methods for manufacturing a wiring board, a microchip and a microlens array substrate, with the use of the method for processing glass.

### Solution to Problem

In order to attain the object, a method for processing glass in accordance with the present invention is a method for processing glass comprising the step of: locally dissolving a part of the glass, which part is located in the vicinity of a processing electrode, by causing the processing electrode, that acts as an anode, to be in contact with or in proximity to the glass in a processing solution, the processing solution containing fluoride ions, water, and an acid-generating assistant agent which is more easily oxidized than water and generates hydrogen ions upon being oxidized.

The wording “generate hydrogen ions upon being oxidized” means that hydrogen ions are generated (i) by a reaction of a substance (in this case, an acid-generating assistant agent) with water when the substance is oxidized, or (ii) by a reaction of a product, obtained by oxidation of the substance, with water.

In a case where a processing electrode, that acts as an anode, is caused to be in contact with or in proximity to glass in a processing solution containing fluoride ions and water, water on a surface of the processing electrode is oxidized to generate hydrogen ions. Accordingly, in the vicinity of the processing electrode, concentration of hydrogen fluoride, hydrogen fluoride ions or dihydrogen difluoride would relatively be increased. In this method, since a glass dissolving capacity of the processing solution can be increased locally in the vicinity of the processing electrode, the glass can be dissolved locally in the vicinity of the processing electrode.

Therefore, according to the method, glass can be processed (wet etched) without being mechanically and thermally damaged. Moreover, the method employing wet etching does not require forming mask patterns by photolithography. It is thus possible to process glass with fewer steps and to achieve the processing at a lower cost than of the conventional methods. It is further possible to finely process glass.

The processing solution used in the present invention contains particularly an acid-generating assistant agent which is more easily oxidized than water and generates hydrogen ions upon being oxidized. Therefore, the oxidation of the acid-generating assistant agent on the surface of the processing electrode allows the generation of additional hydrogen ions in the processing solution. As a result, local concentration of hydrogen fluoride, hydrogen fluoride ions, or dihydrogen difluoride in the vicinity of the processing electrode is further increased, as compared with a case where no acid-generating assistant agent is used. In the method in accordance with the present invention, a glass dissolving capacity of the processing solution can thus be improved in the vicinity of the processing electrode, as compared with a case where no acid-generating assistant agent is used. Hence, the processing speed can further be increased in the present method as compared with the method employing the processing solution which does not contain an acid-generating assistant agent.

### Advantageous Effects of Invention

As stated above, a method for processing glass in accordance with the present invention includes: locally dissolving a part of the glass, which part is located in the vicinity of a processing electrode, by causing the processing electrode, that acts as an anode, to be in contact with or in proximity to the glass in a processing solution, the processing solution containing fluoride ions, water, and an acid-generating assistant agent which is more easily oxidized than water and generates hydrogen ions upon being oxidized. Accordingly, glass can be processed with fewer steps and thus at less cost than of the conventional methods. This allows an increase in processing speed of glass.

### BRIEF DESCRIPTION OF DRAWINGS

FIG. 1 is a diagram illustrating oxidation reaction of an acid-generating assistant agent in the vicinity of a processing electrode, in a method for processing glass according to an embodiment of the present invention.

FIG. 2 is a diagram illustrating schematically how a glass processing apparatus employed in Embodiment 1 of the present invention is configured.

FIG. 3 is a diagram illustrating a processing principle of the method for processing glass in accordance with the present embodiment.

FIG. 4 illustrates processing states of a glass substrate 6, which are obtained when processing liquid containing no acid-generating assistant agent is used. (a) of FIG. 4 illustrates a processing state, in which a low potential is applied to a processing electrode, (b) of FIG. 4 illustrates a processing state in which a high potential is applied to the processing electrode, and (c) of FIG. 4 is an enlarged view of a circle illustrated in (b) of FIG. 4.

FIG. 5 illustrates processing states of the glass substrate. (a) of FIG. 5 illustrates processing state of the glass substrate, which is obtained in a case where (i) the processing liquid containing no acid-generating assistant agent is used and (ii) an electric potential of +0.9V is applied to the processing electrode. (b) of FIG. 5 illustrates a processing state of the glass substrate, which is obtained in a case where (i) a processing liquid containing an acid-generating assistant agent is used and (ii) potential of +0.9V is applied to the processing electrode.

FIG. 6 schematically illustrates how the processing is carried out in the vicinity of the processing electrode, in a case where a processing liquid containing no acid-generating assistant agent is used. (a) through (c) of FIG. 6 illustrate different states.

FIG. 7 schematically illustrates how the processing is carried out in the vicinity of the processing electrode, in a case where processing liquid containing an acid-generating assistant agent, which generates no bubble, is used. (a) through (c) of FIG. 7 illustrate different states.

FIG. 8a is a photomicrograph of a processed surface of a glass substrate, which surface is obtained in Example 1 in which an etching solution B is used. The processed surface includes a processed part.

FIG. 8b illustrates a cross sectional profile of the processed glass substrate illustrated in FIG. 8a.

FIG. 9 is a photomicrograph of a surface of a processed glass substrate, which surface is obtained in Comparative Example 1 in which an etching solution A is used. The processed surface includes a processed part.

FIG. 10a is a photomicrograph of a processed surface of a glass substrate, which surface is obtained in Comparative Example 2 in which the etching solution A is used. The processed surface includes a processed part.

FIG. 10b is a cross sectional profile of the processed glass substrate illustrated in FIG. 10a.

FIG. 11a is a photomicrograph of a surface of a processed glass substrate, which surface is obtained in Example 2 in which an etching solution C is used. The processed surface includes a processed part.

FIG. 11b is a cross sectional profile of the processed glass substrate illustrated in FIG. 11a.

FIG. 12a is a photomicrograph of a processed surface of a glass substrate, which surface is obtained in Comparative Example 3 in which the etching solution A is used. The processed surface includes a processed part.

FIG. 12b is a cross sectional profile of the processed glass substrate illustrated in FIG. 12a.

FIG. 13 is a cross sectional view of an example of an electrode-supported substrate comprising processing electrodes, which are used in the method for processing glass according to Embodiment 2 of the present invention.

FIG. 14 illustrates, in an order in which steps are processed, a method for simultaneously forming a plurality of grooves in the glass substrate by using, as processing tools in Embodiment 2 of the present invention, the electrode-supported substrate including blade-shaped processing electrodes. (a) through (c) of FIG. 14 illustrate the respective steps.

FIG. 15 illustrates, in an order in which steps are processed a method for forming buried wires in the glass substrate by using, as processing tools in Embodiment 3 of the present invention, an electrode-supported substrate including rod-shaped processing electrodes. (a) through (f) of FIG. 15 illustrate the respective steps.

FIG. 16 is a plan view illustrating a recess pattern of a microchip formed in Embodiment 4 of the present invention.

FIG. 17 illustrates, in an order in which steps are processed, a method for forming the recess pattern of the microchip in a glass substrate in Embodiment 4 of the present invention. (a) through (d) of FIG. 17 illustrate the respective steps.

FIG. 18 illustrates, in an order in which steps are processed, a method for forming through-type electrodes in a glass substrate in Embodiment 5 of the present invention. (a) through (f) of FIG. 18 illustrate the respective steps.

FIG. 19 illustrates, in an order in which steps are processed, a method for simultaneously forming a plurality of recess patterns for a microlens in a glass substrate in Embodiment 6 of the present invention. (a) through (d) of FIG. 19 illustrate the respective steps.

### DESCRIPTION OF EMBODIMENTS

### Embodiment 1

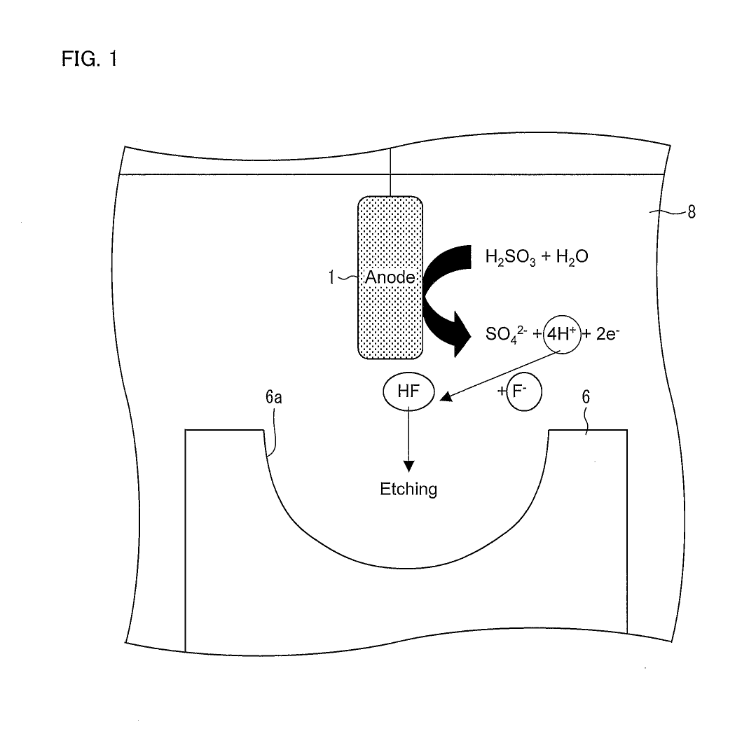

An embodiment of the present invention will be described below with reference to FIGS. 1 through 12b.

A method for processing glass in accordance with the present embodiment is a method for processing glass by use of wet etching. According to the method for processing glass of the present embodiment, glass is processed by causing a processing electrode, that acts as an anode, to be in contact with or in proximity to the glass in processing liquid (processing solution) containing F⁻ (fluoride ions), water, and an acid-generating assistant agent which is more easily oxidized than water and generates hydrogen ions upon being oxidized, so that a part of the glass is locally dissolved, which part is located in the vicinity of the processing electrode.

The present embodiment will mainly describe an example of processing of glass in which a groove or hole is formed in glass. Note, however, that the present embodiment is not limited to this.

Note also that the shape of the groove is not particularly limited and therefore may be a V-shape or U-shape. And, the hole may be a simple depression or a through-hole. Hereinafter, except where distinction is required, a hole and a groove are collectively referred to as a “hole”.

### <Processing Apparatus>

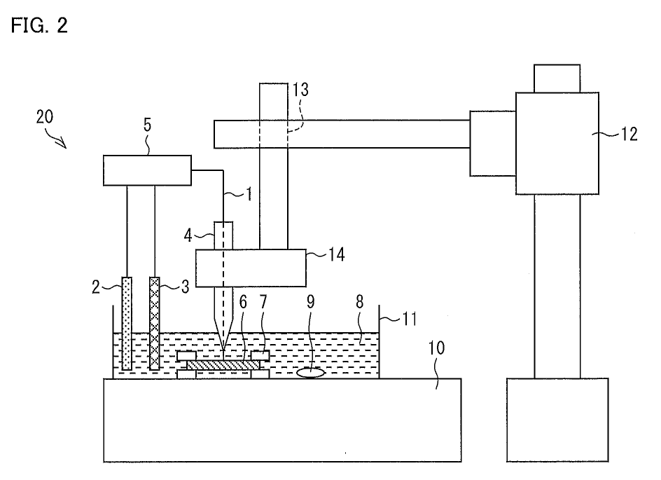

The following description will first schematically discuss, with reference to FIG. 2, a glass processing apparatus for use in a method for processing glass in accordance with the present embodiment.

FIG. 2 is a diagram illustrating schematically how the glass processing apparatus employed in the present embodiment is configured.

As illustrated in FIG. 2, the glass processing apparatus 20 employed in the present embodiment includes a tank 11 (container) for processing liquid, a processing electrode 1, a counter electrode 2, a reference electrode 3, a processing electrode holding tube 4, an electric potential control device 5, a heat insulation plate 10 with a stirring function, a processing tool supporting stand 12, and a supporting member 14.

The tank 11 is a container for accommodating processing liquid (processing solution) 8 containing F⁻, water and an acid-generating assistant agent (assistant agent), and a glass substrate (glass) 6 to be processed. The processing liquid 8 will be described in detail later.

A container, which has (high) resistance to the processing liquid 8 and has a dimension that is large enough to accommodate the glass substrate 6 that is an object to be processed, can be employed as the tank 11. Note that the wording used in the present embodiment “has (high) resistance to the processing liquid 8” means “is not likely to be dissolved in the processing liquid 8 or is not likely to be corroded (is preferably not dissolved or corroded). In other words, the wording means that the dissolving or the corrosion of the tank 11 is negligible, as compared with that of the glass substrate that is an object to be processed.

A material of the tank 11 is not limited to a specific one, provided that the tank 11 has resistance to the processing liquid 8. Examples of such a material encompass polypropylene and polytetrafluoro-ethylene (Registered Trademark “Teflon”). Preferably, a thermostatic chamber is used as the tank 11. In a case where the tank 11 is disposed, for example, on the heat insulation plate 10 with a stirring function, it is possible to heat the processing liquid 8 in the tank 11. The processing liquid 8 in the tank 11 can be stirred by rotating a stirring bar 9 in the tank 11.

Further, there is provided (fixed), in the tank 11, a fixing jig 7 for fixing the glass substrate 6. The fixing jig 7 is made from Teflon (Registered Trademark), and is configured to hold top and bottom surfaces of end parts of the glass substrate 6 and to clamp the glass substrate 6 with respective screws.

As illustrated in FIG. 2, the processing electrode 1, the counter electrode 2, and the reference electrode 3 are provided in the tank 11 so as to be in contact with the processing liquid 8. Each of the processing electrode 1, the counter electrode 2 and the reference electrode 3 are connected to the electric potential control device 5.

The electric potential control device 5 electrochemically controls electric potential to be applied to the processing electrode 1. A potentiostat or a galvanostat, for example, can be employed as the electric potential control device 5. The electric potential control device 5 electrochemically applies a positive electric potential to the processing electrode 1. In the present embodiment, the wording “a positive electric potential is electrochemically applied to the processing electrode 1” means that an electric potential of higher than 0V is applied on the premise that an electric potential of the reference electrode 3 is a reference electric potential. That is, in the present embodiment, the processing electrode 1 is used as an anode, and the counter electrode 2 acts as a cathode.

The processing electrode 1 is an electrode which acts as a processing tool for processing the glass substrate 6. The electrochemical positive electric potential causes the processing electrode 1 to take electrons from the processing liquid 8 which is in contact with the processing electrode 1. This causes water in the processing liquid 8 to be oxidized.

The processing electrode 1 is held by the processing electrode holding tube 4 so as to be vertical to a surface of the glass substrate 6, which surface is to be processed. The processing electrode holding tube 4 is a tube for fixing the processing electrode 1.

The processing electrode holding tube 4 is obtained by making a through-hole for holding the processing electrode 1 in the center of a rod having a tapered shape toward the object to be processed. Two screw holes are made in a side surface of the rod so as to extend in a horizontal direction. According to the processing electrode holding tube 4, the processing electrode 1 is held, in the horizontal direction, by screws inserted into the respective two screw holes. This allows the processing electrode 1 to be fixed. A material of the rod is not particularly limited and can therefore be, for example, polytetrafluoro-ethylene (Registered Trademark “Teflon”).

The processing electrode holding tube 4 is supported by the supporting member 14. The supporting member 14 is held by the processing tool supporting stand 12, by being inserted into an opening 13 made in the processing tool supporting stand 12. A material of the processing electrode holding tube 4 is not particularly limited, provided that the processing electrode holding tube 4 has resistance to the processing liquid 8. This is because the processing electrode holding tube 4 also comes into contact with the processing liquid 8. Therefore, polytetrafluoro-ethylene (Registered Trademark “Teflon”), for example, can be employed as the material of the processing electrode holding tube 4.

In the present embodiment, the supporting member 14 moves downward in the direction of gravity by the weights of the processing electrode holding tube 4 and of the supporting member 14, and therefore the processing electrode 1 moves downward. This causes the processing electrode 1 to come into contact with the glass substrate 6. Since a processing direction can be determined by utilizing the weights of the respective members, the configuration of the apparatus is simplified. Even when the glass substrate 6 is dissolved, it is possible to keep a state where the processing electrode 1 and the glass substrate 6 are in contact with each other, without providing special means for moving the processing electrode 1. Therefore, the moving of the processing electrode 1 requires no electric power. Specifically, it is possible to further dissolve the glass substrate 6 by merely keeping the state in which the positive electric potential is being applied to the processing electrode 1. It is therefore possible to achieve the processing of the glass substrate 6 at a lower cost.

Note, however, that the processing method and the processing apparatus of the present invention are not limited to the above-mentioned configurations, provided that at least one of the processing electrode 1 and the glass substrate 6 can be moved while the processing electrode 1 and the glass substrate 6 are being in contact with or in proximity to each other.

For example, the processing method and the processing apparatus of the present invention can have a configuration in which the processing electrode 1 is moved by use of an appropriate movable stage so as to be moved and come into contact with the glass substrate 6. The configuration offers an advantage in that the processing direction can be freely controlled. This is because the processing electrode 1 can be moved in a desired direction.

Note that, in a case where processing is carried out while using the mobile stage, the processing electrode 1 does not have to be in contact with the glass substrate 6 but has to be in proximity to the glass substrate 6. For example, a surface of the processing electrode 1 can be away, by a distance of not more than 10 μm, from a surface to be processed, of the glass substrate 6. According to the processing method of the present invention, glass is dissolved by HF (hydrogen fluoride), HF₂⁻, or H₂F₂, each of which is generated in the vicinity of the surface of the processing electrode 1 (later described). HF (hydrogen fluoride), HF₂⁻, and H₂F₂ can move from one place to another. This is why the processing electrode 1 does not have to be in contact with the glass substrate 6.

Instead of moving the processing electrode 1, it is possible to move the glass substrate 6. Alternatively, instead of moving the processing electrode 1, it is possible to move (i) the processing electrode 1 and (ii) the glass substrate 6.

Further, the processing apparatus 20 can include a position detection means (not illustrated) for detecting positions of respective of the processing electrode 1 and the glass substrate 6.

The counter electrode 2 is a feeding electrode for causing an electric current to flow through the processing electrode 1. The reference electrode 3 is an electrode for controlling the electric potential. That is, the electric potential control device 5 is an electric potential control device in which three-electrodes are involved in controlling of the electric potential. Specifically, since the counter electrode 2 and the reference electrode 3 are used, it becomes easier to control the electric potential of the processing electrode 1, serving as a working electrode, with respect to the reference electrode 3.

Note that the processing electrode 1 is provided in the tank 11 so as to be in contact with or in proximity to the glass substrate 6 in the processing liquid 8. Whereas, the locations of the counter electrode 2 and the reference electrode 3 are not particularly limited, provided that the counter electrode 2 and the reference electrode 3 are provided in the tank 11 so as to be in contact with the processing liquid 8.

Materials of the processing electrode 1, the counter electrode 2, and the reference electrode 3 are not particularly limited, provided that the processing electrode 1, the counter electrode 2, and the reference electrode 3 each are made from an electrode material having (high) resistance to the processing liquid 8.

Examples of the electrode material of the processing electrode 1 encompass conductive materials such as platinum, gold, iridium, and their alloys. An electrode such as platinum line (platinum wire) or a platinum plate can be used as the counter electrode 2. An electrode such as a silver line, a silver-silver chloride electrode or a saturated calomel electrode is used as the reference electrode 3.

Note that the electrode materials can be provided at least on surfaces of their respective electrodes. Therefore, the electrodes can have a configuration in which layers made from the respective electrode materials are provided on surfaces of base substances, each serving as center core, of the respective electrodes.

In case of, for example, the processing electrode 1, the processing electrode 1 can be configured so that a center core part (base substance) of the processing electrode 1, which is made from a conductive material such as copper or nickel, is coated with a noble metal such as platinum or iridium, the noble metal being different from the conductive material of the center core part. Alternatively, the processing electrode 1 can be configured so that a base substance of the processing electrode 1, which is made from a hard material such as tungsten, is coated with a noble metal such as platinum or iridium. Note that, in this case, the material of the base substance is not limited only to tungsten. Therefore, examples of the base substance encompass materials such as carbon fiber, iron, steel or silicon carbide.

Alternatively, a part of the processing electrode 1 can be coated with a non-conductive material such as (i) resin including polytetrafluoro-ethylene (Registered Trademark “Teflon”) or (ii) ceramics. Such a part of the processing electrode 1, for example, excludes the processing surface which is in contact with the glass substrate 6 serving as the object to be processed.

Such a part of the processing electrode 1 excluding the processing surface includes a conductive wire section, which is a connecting part for connecting the processing electrode 1 to the electrical potential control device 5.

Since the part of the processing electrode 1 excluding the processing surface is coated with a non-conductive material, it is possible to limit a region where the acid is generated only to required part(s). Accordingly, it is possible to prevent unnecessary part(s) in the glass substrate 6 from being processed, and it is therefore possible to reduce the amount of the electric current to be supplied to the processing electrode 1.

Note that, in the present embodiment, (i) a method for forming a layer made from an electrode material (conductive layer) on a base substance and (ii) a method for coating a part of the processing electrode 1 with a non-conductive material are not particularly limited. In a case where a non-conductive material layer is formed, it is possible to employ a method such as a coating method, a plating method, or a depositing method, depending on the type of the non-conductive material. Similarly, in a case where a conductive material layer is formed, it is possible to employ a method such as a coating method, a plating method, or a depositing method, depending on the type of the conductive material. Alternatively, it is possible to form a conductive layer by (i) screen-printing an electrode material with respect to a surface of the base substance and then (ii) exposing the electrode material.

Also note that the shape and the number of each of the base substance and the resulting processing electrode 1 are not particularly limited, and therefore they can be appropriately determined in accordance with the way of the processing and the shape of the attained product. A processing electrode, such as a wire, a blade or needle, whose processing surface has a shape of line or point, can be appropriately used as the processing electrode 1. Examples of the wire encompass (i) a single tensioned straight line and (ii) combined and netted plenty of wires.

Further note that the processing electrode 1 can have a plurality of electrode sections which project toward a surface, to be processed, of the glass substrate 6. This allows the glass substrate 6 to be simultaneously processed in a plurality of regions. As a matter of course, a plurality of processing electrodes 1 can be arranged instead of a single processing electrode 1. This also allows the glass substrate 6 to be simultaneously processed in a plurality of regions. Further, in a case where combined and netted plenty of wires as early described, it is possible to simultaneously cut plenty of glass substrates 6.

According to the present embodiment, as illustrated in FIG. 2, (i) the glass substrate 6 which is an object to be processed, the processing electrode 1, the counter electrode 2, and the reference electrode 3 are immersed in the processing liquid 8 in the tank 11, (ii) the processing electrode 1 is provided so as to be in contact with or in proximity to the glass substrate 6, and then (iii) a positive electric potential is electrochemically applied to the processing electrode 1. This allows part of the glass substrate 6 to be locally dissolved, which part is located in the vicinity of the processing electrode 1.

### <Processing Liquid 8>

According to the method for processing glass of the present embodiment, the processing liquid 8 contains F⁻, water, and an acid-generating assistant agent, as early described.

Note that an acid-generating assistant agent is not particularly limited, provided that the acid-generating assistant agent is a substance which is more easily oxidized than water and generates hydrogen ions upon being oxidized.

Examples of the substance, which is more easily oxidized than water, encompass (i) a substance whose oxidation-reduction potential is lower than that of water and (ii) a substance whose exchange current density during oxidation reaction is higher than that during oxidation reaction of water. A substance, whose oxidation-reduction potential is lower than that of water, is more easily oxidized in response to a certain applied electric potential, such as an electric potential near the oxidation-reduction potential of water. This causes more hydrogen ions H⁺ to be generated than that generated during oxidation reaction of water. Accordingly, it is possible to locally increase the concentration of the acid which can dissolve the glass substrate 6.

In contrast, in a case where an exchange current density of a substance is higher than that of water, during oxidation reaction, such a substance is more rapidly oxidized than water in response to an applied electric potential higher than the oxidation-reduction potential of the substance. Since this substance, even if it has the oxidation-reduction potential higher than that of water, is more rapidly oxidized than water, the substance can generate more hydrogen ions H⁺ than that generated in oxidation reaction of water, in response to an electric potential of not lower than the oxidation-reduction potential of the acid-generating assistant agent. Accordingly, it is possible to locally increase the concentration of the acid which can dissolve the glass substrate 6.

Examples of the substance, which can generate hydrogen ions upon being oxidized, encompass (i) a substance which generate hydrogen ions directly and (ii) a substance which generate hydrogen ions indirectly.

Here, the wording “generate hydrogen ions directly upon being oxidized” means that hydrogen ions are generated (i) from an acid-generating assistant agent by oxidation of the acid-generating assistant agent or (ii) from water molecule when the acid-generating assistant agent is oxidized.

And the wording “generate hydrogen ions indirectly upon being oxidized” means that, when an acid-generating assistant agent is oxidized, an intermediate substance is generated, and then the intermediate substance reacts with water, so that hydrogen ions are generated from the intermediate substance or from the water.

Examples of the acid-generating assistant agent encompass sulfite salt such as sodium sulfite and ammonium sulfite. Sulfite salt has (i) an oxidation-reduction potential lower than that of water and (ii) an exchange current density during oxidation reaction higher than that of water. Accordingly, sulfite salt can generate a larger number of hydrogen ions in response to a low electric potential. This allows an increase in processing speed even in response to a low electric potential. Further, sulfite salt directly generates hydrogen ions upon being oxidized, as expressed in the following formula (1):

H₂SO₃+H₂O→SO₄²⁻+4H⁺+2e⁻ (1)

Besides sulfite salt, sodium chloride can be used as the acid-generating assistant agent. Sodium chloride is a substance which has an oxidation-reduction potential higher than that of water, but still has an exchange current density during oxidation reaction, higher than that of water.

Sodium chloride is oxidized, so as to generate Cl₂ that is an intermediate substance, as expressed in the following formula (2):

2Cl⁻→Cl₂+2e⁻ (2)

Then, Cl₂ reacts with water, so as to generate hydrogen ions H⁺, as expressed in the following formula (3):

Cl₂+H₂O→H⁺+Cl⁻+HClO (3)

That is, sodium chloride indirectly generates hydrogen ions upon being oxidized.

The acid-generating assistant agent is preferably a substance which generates no bubble when the substance is oxidized under the condition in which the processing method of the present invention is actually implemented, that is, a substance which generates, upon being oxidized, only products which are dissolved in the processing liquid 8. The products which are dissolved in the processing liquid 8 mean products such as electric charge, an ionic substance, and a liquid substance, which generate no bubble in the processing liquid 8 under the condition in which the processing method of the present invention is implemented. Examples of such an acid-generating assistant agent encompass the above-mentioned sodium sulfite. The use of such an acid-generating assistant agent enables to (i) carry out the processing at a low electric potential and (ii) effectively prevent a surface to be processed from becoming rough due to bubbles (later described). The prevention of the surface from becoming rough will be described later.

The processing liquid 8 is not limited to a specific one, provided that it contains fluoride ions, water, and an acid-generating assistant agent. And, a solution for generating fluoride ions is not particularly limited.

Examples of the solution for generating fluoride ions encompass an ammonium fluoride aqueous solution and a mixture of hydrofluoric acid and alkali. Examples of the mixture of hydrofluoric acid and alkali encompass a mixture of hydrofluoric acid and ammonia water or sodium hydroxide aqueous solution.

Glass is in general dissolved by strong alkali (for example, pH=9.8 or more), although it depends on the composition of the glass. Further, SiO₂ (silicon dioxide), that is a main ingredient of glass, is dissolved by HF (hydrogen fluoride), HF₂⁻ (hydrogen difluoride ions) or H₂F₂ (dihydrogen difluoride). Accordingly, in order to locally process glass, the processing liquid 8 preferably has a pH falling within a rage from mild acidic to alkaline (pH=6 to 9), and more preferably has a pH falling within a range from neutral to alkalescent (pH=7 to 8).

A content of the acid-generating assistant agent in the processing liquid 8 is preferably more than 0 but not more than the solubility of the acid-generating assistant agent, in view of preventing the acid-generating assistant agent from being remained undissolved and precipitated, and more preferably not less than one-half of the solubility but not more than the solubility, in view of increasing the concentration of the acid-generating assistant agent so that a faster processing speed is obtained.

### <Processing Principle>

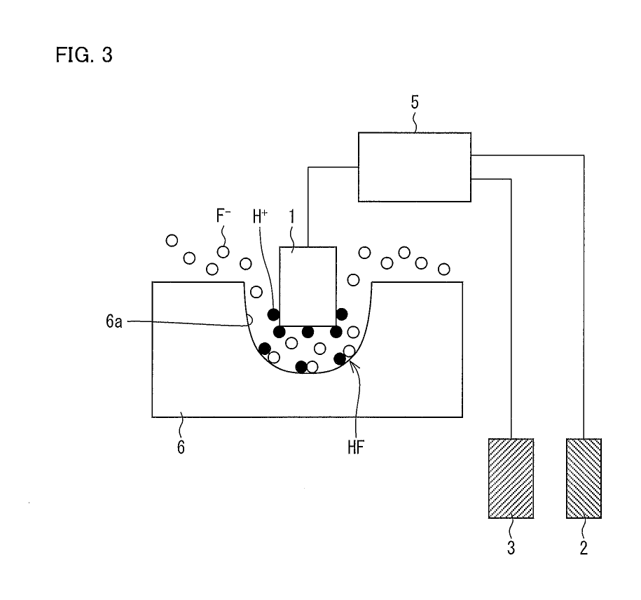

The following description will discuss the processing principle in the method for processing glass of the present embodiment, with reference to mainly FIGS. 1 and 3.

The processing principle in the present processing method will be first described below with reference to FIG. 3.

FIG. 3 is a diagram illustrating a processing principle of the method for processing glass of the present embodiment. FIG. 1 is a diagram illustrating oxidation reaction of an acid-generating assistant agent in the vicinity of a processing electrode 1, in the method for processing glass of the present embodiment. Note that FIG. 3 illustrates, as the processing liquid 8, merely hydrogen ions (H⁺), fluoride ions (F⁻), and hydrogen fluoride (HF), but does not illustrate the whole ingredients of the processing liquid 8.

As early described, it is known that SiO₂, which is a main ingredient of glass, is dissolved by HF, HF₂⁻ or H₂F₂. Hence, a concentrated hydrogen fluoride aqueous solution (concentrated hydrofluoric acid), containing a large amount of HF, HF₂⁻ or H₂F₂, has a function to dissolve glass.

In contrast, it is known that the function of F⁻ to dissolve glass is weak. For example, HF reacts with SiO₂ contained in glass, as expressed in the following formula (4), so as to produce hydrogen hexafluorosilicate (H₂SiF₆) and to dissolve (corrode) glass.

SiO₂+6HF→H₂SiF₆+2H₂O (4)

Note that HF, HF₂⁻ and H₂F₂ have respective different concentrations, depending on a pH of liquid solution. For example, in a case where a liquid solution (hereinafter referred to as an “etching solution A”) is obtained by mixing a 40 wt % ammonium fluoride aqueous solution and ultra pure water in the proportion of one to nine, the liquid solution becomes a mild acidic solution whose pH is 6.3. In the liquid solution, HF, HF₂⁻ and H₂F₂ have respective low concentrations. In a case where the glass substrate 6 is merely immersed in the liquid solution, the glass is slowly dissolved. For example, even in a case where the glass is immersed for 5 hours in the liquid solution, the glass is only dissolved by 1 μm or less.

In contrast, in a case where a positive electric potential is applied to the processing electrode 1, there occurs, on a surface of the processing electrode 1, an oxidation reaction of water as expressed in the following formula (5) or (6).

2H₂O→O₂+4H⁺+4e⁻ (5)

2OH⁻→O₂+2H⁺+4e⁻ (6)

Since H⁺ is generated on the surface of the processing electrode 1, the pH becomes low locally in the vicinity of the processing electrode 1 and therefore the degree of acidity is increased. And, H⁺ is chemically bonded to F⁻ which is present in the processing liquid. This causes HF, HF₂⁻ and H₂F₂ to be generated locally so as to have respective high concentrations.

In other words, HF, HF₂⁻ or H₂F₂ has a relatively high concentration locally in the vicinity of the surface of the processing electrode 1 used as the processing tool. As such, when causing the processing electrode 1 to be in contact with or in proximity to the glass substrate 6 (an object to be processed), the rate at which the glass substrate 6 is dissolved is increased in the vicinity of the surface of the processing electrode 1. As a result, the rate at which the glass is dissolved is locally increased in the vicinity of the surface of the processing electrode 1.

Note that a volume of the entire etching solution A (i.e. a volume of the etching solution A in the tank 11 in which the glass substrate 6 is immersed) is much larger than amount of substances of HF, HF₂⁻ and H₂F₂ which are generated locally.

Accordingly, in a location distanced from the processing electrode 1, HF, HF₂⁻ and H₂F₂ have respective low concentrations, and therefore the rate at which the glass substrate 6 is dissolved is very slow. In view of the fact, it is possible to process locally in any region, by causing the processing electrode 1 to be in contact with or in proximity to a region, to be processed, on the glass substrate 6.

The glass substrate 6 is thus dissolved locally in the vicinity of the processing electrode 1, when causing the processing electrode 1, to which a positive electric potential is being electrochemically applied, to be in contact with or in proximity to the glass substrate 6 while the glass substrate 6 is being immersed in the etching solution. Specifically, it is possible to (i) form a hole 6a in the glass substrate 6, as illustrated in FIG. 3, and/or (ii) cut the glass substrate 6, by moving the processing electrode 1 in a direction in which the glass substrate 6 is to be processed.

The processing liquid 8, used in the processing method of the present embodiment, contains an acid-generating assistant agent in addition to the above liquid solution (the etching solution A). The following description will discuss a case in which sodium sulfite is used as an acid-generating assistant agent. However, the acid-generating assistant agent is not limited to this, as early described.

In case of an aqueous solution (hereinafter referred to as an “etching solution B”) in which sodium sulfite is dissolved in the etching solution A so that the sodium sulfite has a concentration of 0.5 mol/L, the etching solution B has a pH of 7.5 and is thus an alkalescent solution. Therefore, HF, HF₂⁻ and H₂F₂ have respective low concentrations in the etching solution B, as is the case with the etching solution A which does not contain sodium sulfite. Accordingly, when the glass substrate 6 is merely immersed in the etching solution B, the rate at which the glass is dissolved is significantly slow.

However, there occurs an oxidation reaction of water (see the formula (5) or (6)) and acid is generated, by applying a positive electric potential to the processing electrode 1, even in a case where the etching solution B is used. Consequently, HF, HF₂⁻ and H₂F₂ with high concentrations are generated locally in the vicinity of the processing electrode 1. It is therefore possible to process the glass substrate 6 locally in the vicinity of the processing electrode 1.

Note that there occurs an oxidation reaction of sulfurous acid as expressed in the foregoing formula (1) (see FIG. 1), in addition to the reaction of the formula (5) or (6). This is because the etching solution B contains sodium sulfite. As a result, hydrogen ions H⁺ are generated (see FIG. 1 and the formula (1)).

The hydrogen ion H⁺, generated in the oxidation reaction of the acid-generating assistant agent, is chemically bonded to F⁻. This causes HF, HF₂⁻ and H₂F₂ to be generated, and ultimately cause HF, HF₂⁻ and H₂F₂ to be involved in the etching of the glass substrate 6, as illustrated in FIG. 1.

According to the present processing method, since the acid-generating assistant agent contained in the processing liquid 8 is thus oxidized on the surface of the processing electrode 1, it is possible to further generate hydrogen ions H⁺ in the processing liquid 8. Consequently, HF, HF₂⁻ or H₂F₂ have respective higher concentrations in the vicinity of the processing electrode 1, as compared with a case in which no acid-generating assistant agent is used. The present processing method allows an improvement in capability of the processing liquid 8 to dissolve the glass in the vicinity of the processing electrode 1, as compared with the case in which no acid-generating assistant agent is used. Consequently, it is possible to increase the rate at which the glass is dissolved, as compared with the case in which no acid-generating assistant agent is contained.

### <Effects of Acid-generating Assistant Agent>

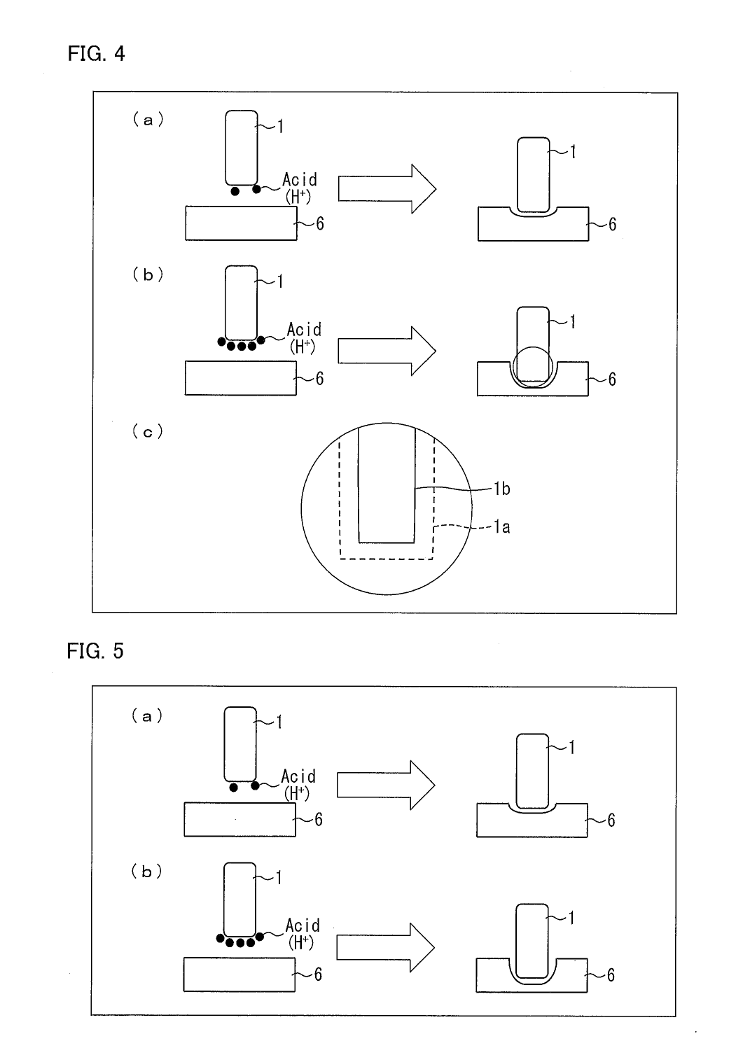

The following description will discuss effects of the present invention brought about by an acid-generating assistant agent, with reference to (a) through (c) of FIG. 4 through (a) through (c) of FIG. 7.

FIG. 4 illustrates processing states of the glass substrate 6, which are obtained when processing liquid containing no acid-generating assistant agent is used. (a) of FIG. 4 illustrates a processing state, in which a low electric potential is applied to a processing electrode 1, (b) of FIG. 4 illustrates a processing state in which a high electric potential is applied to the processing electrode, and (c) of FIG. 4 is an enlarged view of a circle illustrated in (b) of FIG. 4.

The reaction of the formula (5) can thermodynamically be induced when an electric potential of +0.682V (an electric potential with respect to an Ag/AgCl reference electrode; determined from the standard oxidation-reduction potential, where pH=6.3) or more is applied to the processing electrode 1. From the reaction, hydrogen ions H⁺, which are acid, are generated.

In a case where a low electric potential is applied to the processing electrode 1 (see (a) of FIG. 4), a smaller amount of ions H⁺ is generated in the vicinity of the surface of the processing electrode 1, and therefore a processing speed becomes slow. Accordingly, in order to sufficiently increase a reaction rate, it is necessary to apply a higher electric potential (approximately +2V, for example).

As illustrated in (b) of FIG. 4, in a case where a high electric potential is applied to the processing electrode 1, a larger amount of ions H⁺ is generated, and therefore the processing speed becomes faster.

Note, however, that, if an electric potential of, for example, +4V or more is applied to the processing electrode 1 so as to further increase the processing speed, then there will occur a problem that the processing electrode itself is corroded.

(c) of FIG. 4 illustrates how an end part (a circle on the right side of (b) of FIG. 4) of the processing electrode 1 changes before and after the higher electric potential is applied.

If the higher electric potential is applied, then the processing electrode 1 itself will be corroded. This causes a processing electrode 1b, which has been used to carry out processing, to become smaller than a processing electrode 1a (indicated by a dashed line in (c) of FIG. 4) which has not been used to carry out processing (see (c) of FIG. 4).

It is therefore necessary to suppress an electric potential, to be applied to the processing electrode 1, to such a degree that the processing electrode 1 is not corroded, in order to avoid corrosion of the processing electrode 1 in a case where a processing liquid, containing no acid-generating assistant agent, is used. The prevention of the corrosion of the processing electrode 1 contradicts the improvement in processing speed, and it is therefore difficult for them to be compatible with each other.

Meanwhile, the oxidation reaction of the sulfurous acid expressed in the formula (1) can thermodynamically be induced when an potential of −0.48V (an potential with respect to an Ag/AgCl reference electrode; determined from the standard oxidation-reduction potential, where pH=7.5 that is the pH of the etching solution B) or more is applied to the processing electrode 1. The electric potential is far lower than that needed for the oxidation reaction of water.

FIG. 5 illustrates processing states of the glass substrate. (a) of FIG. 5 illustrates a processing state of the glass substrate 6, obtained in a case where (i) a processing liquid containing no acid-generating assistant agent is used and (ii) an electric potential of +0.9V is applied to the processing electrode 1. (b) of FIG. 5 illustrates a processing state of the glass substrate 6, obtained in a case where (i) a processing liquid containing an acid-generating assistant agent is used and (ii) an electric potential of +0.9V is applied to the processing electrode 1.

In a case where the processing is carried out while, for example, an electric potential of +0.9V is applied to the processing electrode 1 (see (a) of FIG. 5), an oxidation reaction rate of water is low. Only a small amount of ions H⁺ is generated in the vicinity of the surface of the processing electrode 1, without an acid-generating assistant agent. As such, the processing speed is slow.

In contrast, in a case where sodium sulfite is added, as an acid-generating assistant agent, to the processing liquid, an oxidation reaction speed of the acid-generating assistant agent is sufficiently fast even with potential of +0.9V. This causes an increase in amount of ions H⁺ generated in the vicinity of the surface of the processing electrode 1, and ultimately causes the processing speed to be fast (see (b) of FIG. 5).

According to the present embodiment, the use of an acid-generating assistant agent makes it possible to carry out the processing in response to a low electric potential. It is therefore not necessary for a high electric potential, which may cause the processing electrode 1 to be corroded, to be applied to the processing electrode 1 so as to increase the processing speed. That is, according to the present embodiment, it is possible to (i) obtain a fast processing speed without applying a high electric potential to the processing electrode 1 and (ii) prevent the problematic corrosion of the processing electrode 1.

In the present embodiment, the electric potential to be applied from the potential control device 5 to the processing electrode 1 (electric potential to be applied between the processing electrode 2 and the reference electrode 3) is 0V or more, and preferably 0.5V or more, with respect to a reference electrode 3 (such as a standard hydrogen electrode).

The electric potential to be applied to the processing electrode 1 is not particularly limited, provided that it is an electrochemically positive electric potential. Note, however, that the higher the electric potential is, the faster the processing speed is. Also note that the electric potential can be applied continuously or intermittently like pulses.

The acid-generating assistant agent has (i) the effect of enabling to process the glass substrate 6 even in response to an applied low electric potential and (ii) the effect of preventing the surface to be processed from becoming rough due to bubbles, as early described.

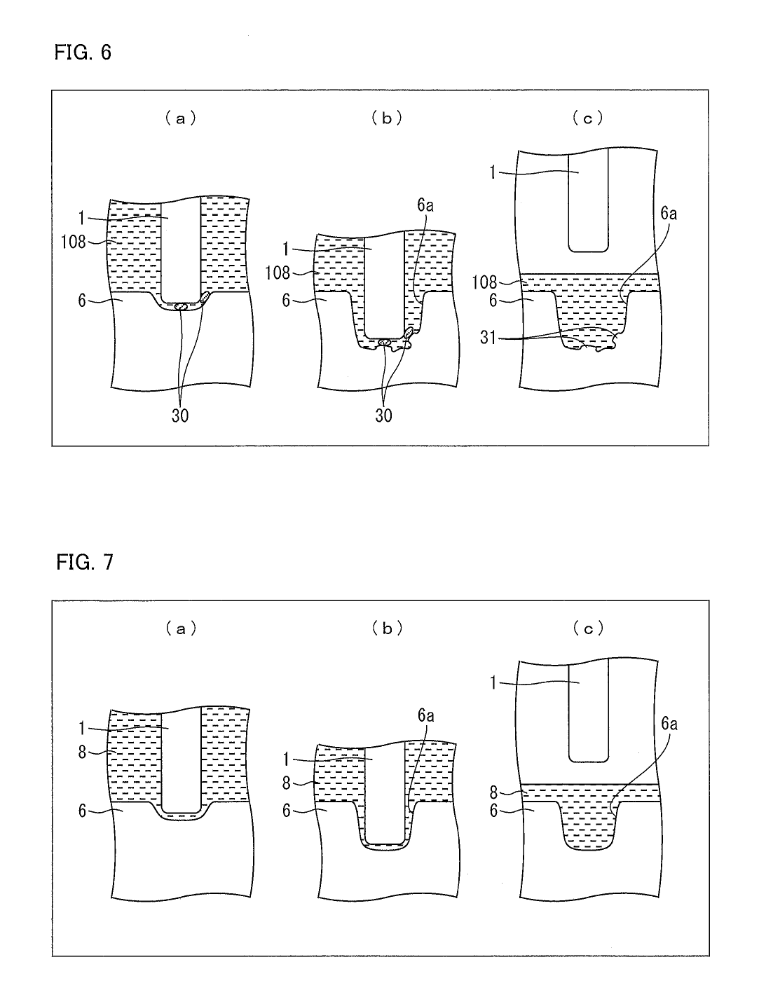

The following description will discuss the mechanism of the effects with reference to (a) through (c) of FIG. 6 and (a) through (c) of FIG. 7.

FIG. 6 schematically illustrates how the processing is carried out in the vicinity of the processing electrode, in a case where a processing liquid containing no acid-generating assistant agent is used. FIG. 7 schematically illustrates how the processing is carried out in the vicinity of the processing electrode, in a case where a processing liquid containing an acid-generating assistant agent, which generates no bubble, is used.

In a case where a processing liquid 108 containing no acid-generating assistant agent is used as illustrated in (a) of FIG. 6, O₂ is generated in response to the generation of ions H⁺ by an oxidation reaction of water, as is clear from the formula (5). Consequently, the O₂ thus generated causes bubbles 30.

The produced bubbles 30 are attached to the surface of the processing electrode 1 or of the glass substrate 6, as illustrated in (a) and (b) of FIG. 6. The bubbles 30 prevent the processing liquid 108 from being contact with parts of the surface(s) of the processing electrode 1 and/or of the glass substrate 6. This causes processing to be locally prevented, as illustrated in (b) of FIG. 6.

Thus, the parts of the glass substrate 6, with which parts the processing liquid 8 is not contact, remain unprocessed as illustrated in (c) of FIG. 6, and the parts thus unprocessed cause protrusions 31 to be formed. Consequently, the cross section of the hole 6a becomes uneven.

In contrast, in a case where the processing liquid 8 containing an acid-generating assistant agent is used as illustrated in (a) through (c) of FIG. 7, hydrogen ions H⁺ can be generated utilizing the oxidation reaction of the acid-generating assistant agent as early described, without utilizing the oxidation reaction of water. Note that, in a case where an acid-generating assistant agent such as sodium sulfite, which generates no bubble, is used, the reaction illustrated in FIG. 1 and expressed in the formula (1) also generates hydrogen ions H⁺.

In this case, SO₄²⁻, which is dissolved in the processing liquid 8 is generated besides the ions H⁺. The reaction expressed in the formula (1) is induced in preference to the oxidation reaction of water.

In a case where the processing liquid 8 containing an acid-generating assistant agent is used, bubbles 30 are hardly produced as illustrated in (a) and (b) of FIG. 7. As such, the processing is not locally prevented by the bubbles 30. It is therefore possible to form, in the glass substrate 6, a hole 6a whose cross section has few concavity and convexity (see (c) of FIG. 7).

The following description will discuss, with examples, a method for processing glass of the present embodiment. Note that the present invention is not limited to the examples.

### Example 1

In Example 1, a processing, in which a hole was made in the glass substrate 6, was carried out with the use of the processing apparatus 20 as illustrated in FIG. 2.

First described is a configuration of the processing apparatus 20 used in Example 1.

In Example 1, platinum wire (The Nilaco Corporation, 100 μm in diameter and 10 cm in length) was used as the processing electrode 1. A platinum plate was used as the counter electrode 2. A silver/silver chloride reference electrode was used as the reference electrode 3. The silver/silver chloride reference electrode was connected to the processing liquid 8 via a salt bridge (not illustrated) filled with a saturated potassium chloride aqueous solution. The three electrodes, i.e., the processing electrode 1, the counter electrode 2 and the reference electrode 3 were electrically connected to a potentiostat/galvanostat (Product name: HABF5001, Hokuto Denko Corporation), that is the potential control device 5.

The stirring bar 9 for stirring the processing liquid 8 was provided in the tank 11. The tank 11 was disposed on the heat insulation plate 10 with a stirring function. The stirring bar 9 was rotated to stir the processing liquid 8. A container made from polypropylene, whose capacity is 300 mL, was used as the tank 11.

The tank 11 was filled with the processing liquid 8 of 85 mL. A liquid solution (the etching solution B) was used as the processing liquid 8. In the liquid solution, 5.4 g sodium sulfite serving as an acid-generating assistant agent was dissolved (concentration: 0.5 mol/L) in a mixture of 85 mL in which (i) a 40 wt % ammonium fluoride aqueous solution and (ii) ultra pure water were mixed in the proportion of one to nine (volume ratio). The temperature of the processing liquid 8 was maintained at 25° C. by means of the heat insulation plate 10 with a stirring function.

A glass plate of Corning Incorporated “EAGLE XG” (Product name, 0.7 mm in thickness), which was cut out in a size of 20 mm×20 mm, was used as the glass substrate 6 that was to be processed. The glass substrate 6 was fixed by the fixing jig 7.

The processing electrode 1 was held by the processing electrode holding tube 4 so as to be perpendicular to a surface, to be processed, of the glass substrate 6. A rod was used as the processing electrode holding tube 4. The rod (i) was made from Teflon (Registered Trademark), (ii) had a tapered shape toward an object to be processed, and (iii) had a through-hole which had a diameter of 110 μm and was formed in the center of the rod. The rod had, in its side surface, two screw holes each having a diameter of 2 mm. The processing electrode 1 (platinum wire) accommodated into the tube was held in the horizontal direction, by screws inserted into the respective two screw holes. The processing electrode 1 was fixed so as to be exposed in (projected from) a leading end of the processing electrode holding tube 4 by only 1 mm.

As early described, in the processing apparatus 20, the supporting member 14 for supporting the processing electrode holding tube 4 moves downward due to the weights of the processing electrode holding tube 4 and the supporting member 14 (sum total: 20 g). It follows that the processing electrode 1 moves downward. This causes a pressing force of 25 N/mm² to be exerted, by the processing electrode 1, on the glass substrate 6.

The following description will discuss a concrete processing implemented with the use of the processing apparatus 20 and processed results.

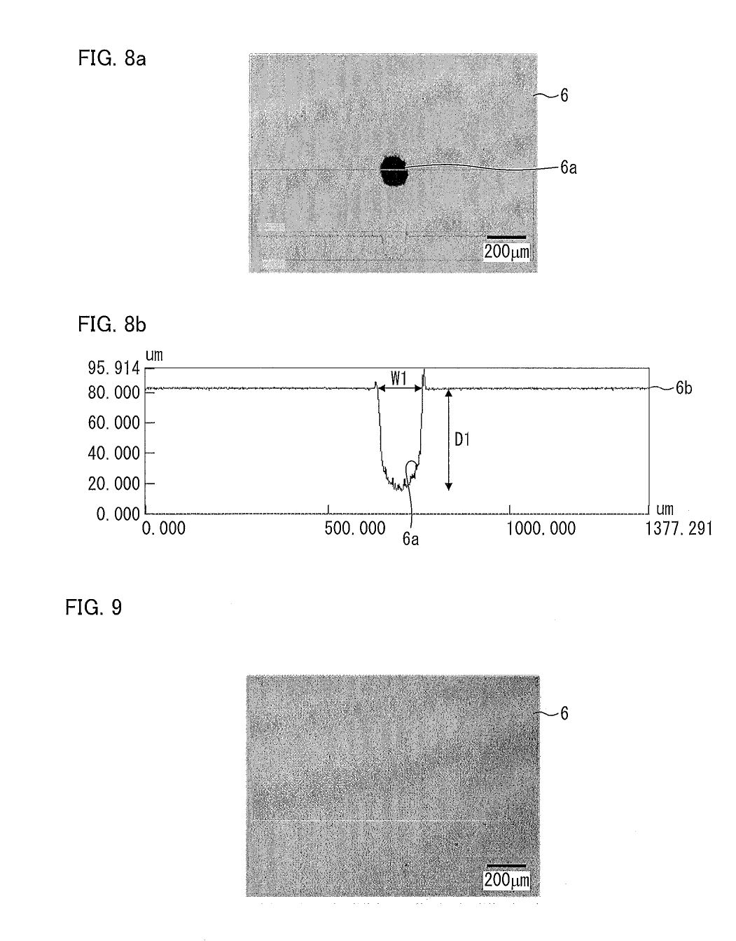

The processing had been carried out for 20 hours, while an electric potential of +0.9V (electric potential with respect to the silver/silver chloride reference electrode 3) was being applied to the processing electrode 1. Then, the glass substrate 6 was took out from the processing apparatus 20, washed with pure water, and was subjected to naturally dried in air. Subsequently, a processed part was observed and photographed with the use of an optical microscope (“BX51” (product name), manufactured by Olympus Corporation). FIGS. 8a and 8b show observed results.

FIG. 8a is a photomicrograph of a processed surface 6b of the glass substrate 6. The processed surface 6b includes a part (processed part) on the glass substrate 6 which part was in contact with the processing electrode 1. As shown in FIG. 8a, the hole 6a was formed in the processed part of the glass substrate 6. The diameter W1 of the hole 6a on a top surface of the glass substrate 6 was 122 μm.

FIG. 8b is a cross sectional profile of the glass substrate 6, which was processed, shown in FIG. 8a. As is clear from the cross sectional profile of FIG. 8b, a depth D1 of the hole 6a is 67 μm.

### Comparative Example 1

According to Comparative Example 1, a processing of the glass substrate 6 was carried out with the use of a solution (the etching solution A) in which (i) no sodium sulfite was contained and (ii) a 40% ammonium fluoride aqueous solution and ultra pure water were mixed in the proportion of one to nine (volume ratio). The result is shown in FIG. 9. Note that, in Comparative Example 1, the processing was carried out under the same conditions as those of the processing which was carried out with the use of the etching solution B, except that the different processing liquid was used.

FIG. 9 is a photomicrograph of the processed surface 6b of the glass substrate 6. The processed surface 6b includes a part (processed part) which was in contact with the processing electrode 1. As shown in FIG. 9, in a case where the processing had been carried out for 20 hours with the use of the etching solution A, no hole 6a was formed.

It was confirmed that the processing of the glass substrate 6 can be carried out with the use of the processing liquid containing sodium sulfite, even in a case where a low electric potential, which does not allow the processing to be carried out with the use of the processing liquid containing no sodium sulfite, is applied.

### Comparative Example 2

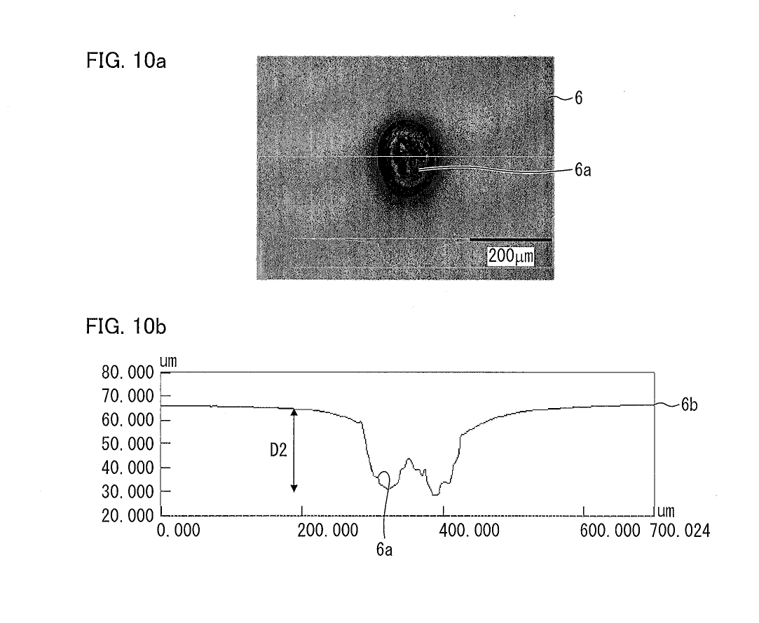

In Comparative Example 2, the processing had been carried out for 20 hours with the use of the etching solution A, while an electric potential of +2.0V was being applied to the processing electrode 1. FIGS. 10a and 10b show observed results.

FIG. 10a is a photomicrograph of the processed surface 6b of the glass substrate 6. The processed surface 6b includes a part (processed part) which was in contact with the processing electrode 1. As shown in FIG. 10a, the hole 6a was formed in the processed part of the glass substrate 6. The diameter W2 of the hole 6a on the top surface of the glass substrate 6 was 151 μm. FIG. 10b is a cross sectional profile of the processed glass substrate 6 shown in FIG. 10a. It is clear from the cross sectional profile of FIG. 10b that the depth D2 at the deepest part of the hole 6a is 23 μm. As is clear from FIG. 10b, the hole 6a had a shape in which many concavity and convexity are formed.

That is, even in the case where the processing was carried out while the electric potential increased to +2.0V was being applied, the hole 6a formed by the processing with the processing liquid containing no sodium sulfite had the smaller depth (23 μm), as compared with the case where the hole 6a, having the larger depth (67 μm), was formed by the processing which was carried out with the use of the processing liquid containing sodium sulfite (the etching solution B) while the low electric potential (+0.9V) was being applied. Note that the depth of 23 μm is approximately one third of the depth of 67 μm. Furthermore, the cross section of the hole 6a of 23 μm included many concavity and convexity and had the diameter on the top surface of the glass substrate 6 largely extended.

It was thus confirmed that it was possible to make more largely faster the speed at which the glass substrate 6 was dissolved by carrying out the processing with the use of the processing liquid 8 containing sodium sulfite than by carrying out the processing with the use of the processing liquid 108 containing no sodium sulfite while the electric potential increased to +2.0V was being applied.

It was further confirmed that, in the case where the processing was carried out with the use of the processing liquid 8 containing sodium sulfite, it was possible to form the hole 6a which had a micro-sized diameter, a more smooth cross sectional shape, and a smaller extension of the diameter on the top surface of the glass substrate 6. The reason is believed to be that the oxidation reaction of water causes oxygen to be generated, the oxygen thus generated produces bubbles, and the bubbles are attached to the surface of the processing electrode 1 or the glass substrate 6, during the processing, so as to locally prevent the processing, whereas the processing which was carried out with the use of the processing liquid 8 containing sodium sulfite generates only a sulfate ion and no bubble.

### Example 2

In Example 2, the processing was carried out with the use of a processing liquid 8 containing sodium chloride, instead of sodium sulfite, which was used as an acid-generating assistant agent. In the processing liquid 8 (hereinafter referred to as an “etching solution C”), 2.5 g sodium chloride serving as an acid-generating assistant agent was dissolved (concentration: 0.5 mol/L) in a mixture of 85 mL in which (i) a 40% ammonium fluoride aqueous solution and (ii) ultra pure water ware mixed in the proportion of one to nine (volume ratio). Further, the etching solution A was used as the processing liquid 108 for a comparative example.

In Example 2, a processing was carried out with the use of soda lime glass (Asahi Glass Co., Ltd., 0.7 mm in thickness) as the glass substrate 6 (an object to be processed), which soda lime glass was cut out in a size of 20 mm×20 mm.

Otherwise, a processing apparatus 20 of the Example 2 had a configuration equivalent to that of the processing apparatus 20 of the Example 1.

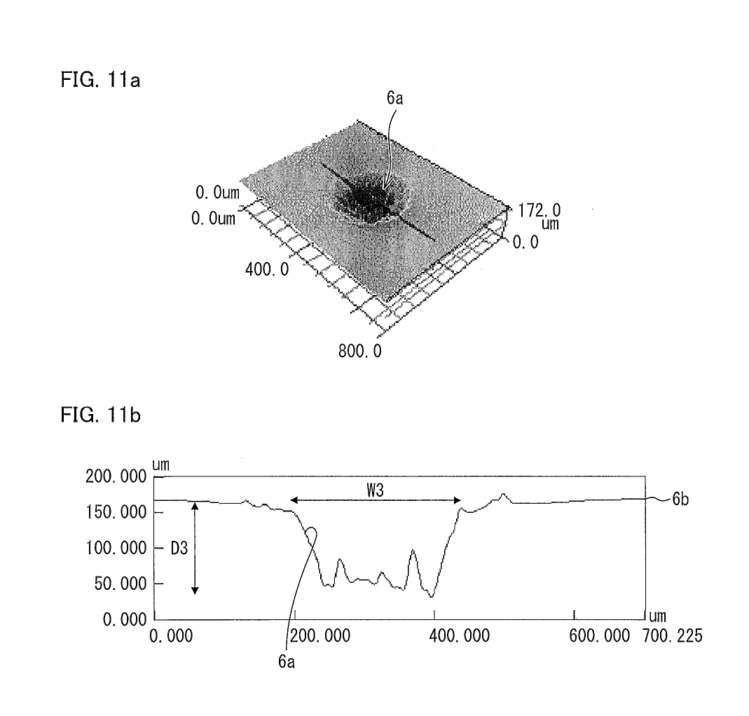

The processing had been carried out for 20 hours, while an electric potential of +2.0V (electric potential with respect to the silver/silver chloride reference electrode 3) was being applied to the processing electrode 1, Then, the glass substrate 6 was took out from the processing apparatus 20, washed with pure water, and was subjected to natural seasoning. Subsequently, a processed part was observed and photographed with the use of an optical microscope “BX51”. FIGS. 11a and 11b show observed results.

FIG. 11a is a photomicrograph of the processed surface 6b of the glass substrate 6. The surface 6b includes a part (processed part) which was in contact with the processing electrode 1. As shown in FIG. 11a, the hole 6a was formed in the processed part of the glass substrate 6. The diameter W3 of the hole 6a on a top surface of the glass substrate 6 was 251 μm.

FIG. 11b is a cross sectional profile of the glass substrate 6, which was processed, shown in FIG. 11a. As is clear from the cross sectional profile of FIG. 11b, a depth D3 of the hole 6a is 136 μm.

### Comparative Example 3

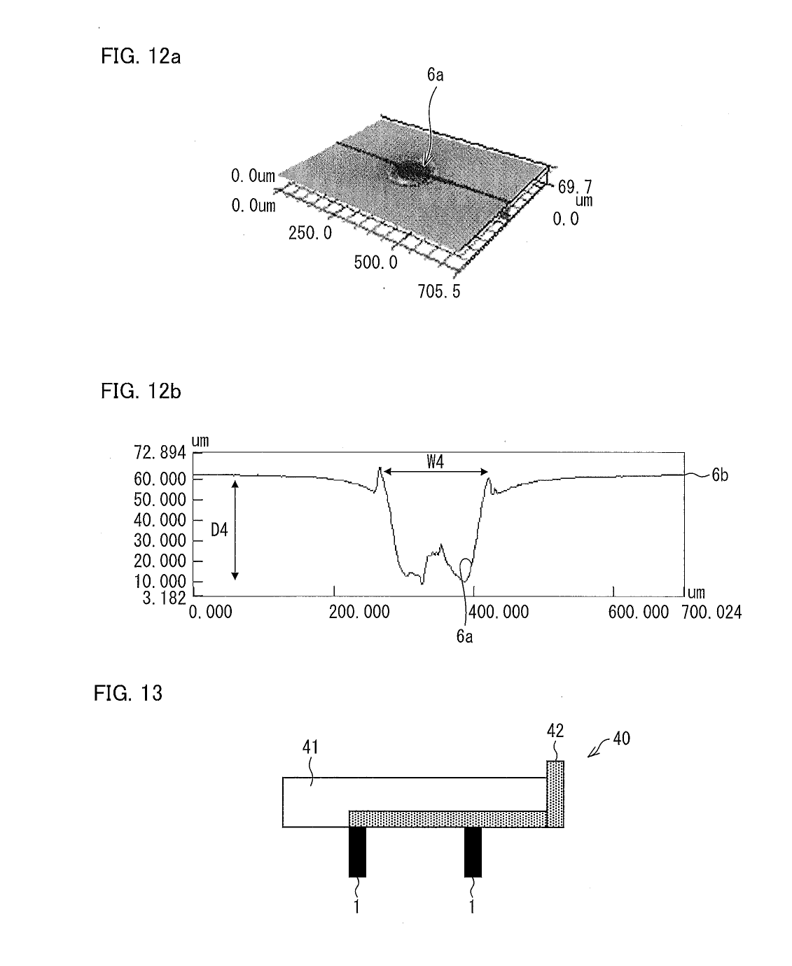

According to Comparative Example 3, the glass substrate 6 was carried out with the use of the etching solution A containing no acid-generating assistant agent, instead of the etching solution C containing sodium chloride. The results are showed in FIGS. 12a and 12b. Note that, in Comparative Example 3, the processing was carried out under the same conditions as those of the processing which was carried out with the use of the etching solution C, except that the different processing liquid was used.

FIG. 12a is a photomicrograph of the processed surface 6b of the glass substrate 6. The processed surface 6b includes a part (processed part) which was in contact with the processing electrode 1. As shown in FIG. 12a, the hole 6a was formed in the processed part of the glass substrate 6. The diameter W4 of the hole 6a on a top surface of the glass substrate 6 was 158 μm.

FIG. 12b is a cross sectional profile of the glass substrate 6, which was processed, shown in FIG. 12a. As is clear from the cross sectional profile of FIG. 12b, a depth D4 of the hole 6a is 53 μm.

It was confirmed that the speed, at which the glass substrate 6 is dissolved, becomes faster in the case where the processing liquid contains sodium chloride than in the case where the processing liquid contains no sodium chloride

It is believed that, when sodium chloride is present in an aqueous solution, an oxidation reaction of chlorine ions as expressed in the formula (2) is induced near an anode, besides an oxidation reaction of water, as disclosed in Patent Literature 12. It is further believed that generated Cl₂ reacts with water as expressed in the formula (3), so that hydrogen ions H⁺ are generated. The reason, why the speed at which the glass substrate 6 was dissolved became faster in Example 2, is believed to be that a series of these reactions caused a greater amount of ions H⁺ to be generated.

Patent Literatures 12 to 14 disclose techniques in which strong acid water is obtained by applying an electric potential to an electrode in a solution to electrolyze the solution, causing H⁺ to be generated. An electrolytic assistant agent, such as sodium chloride, is added to the solution to be electrolyzed. This strong acid water is used in the fields such as medical treatment and food processing industries, for sterilization, bacteria elimination, and disinfection.

In a device for generating electrolysis water as described in Patent Literature 12, for example, there occurs an oxidation of chlorine ions (2Cl⁻→Cl₂+2e⁻) at an anode, as described above, besides oxidation of water (2H₂O→O₂+4H⁺+4e⁻). Cl₂, which was generated, reacts with water (Cl₂+H₂O→H⁺+Cl⁻+HClO) to generate a large amount of hydrogen ions (H⁺), so that electrolysis acid water can be attained.

Note, however, that Patent Literatures 12 to 14 relate to techniques for producing strong acid water with the use of electrolysis and, in particular, to electrolysis water purification devices in which an aqueous solution is obtained by adding an electrolytic assistant agent such as sodium chloride to raw water such as tap-water, and the aqueous solution, which is obtained, is electrolyzed into strong acid water and strong alkali water. Patent Literatures 12 to 14 relate to the technical fields different from that of the present invention and thus are not intended to use the above effect for processing glass as in the present invention.

The oxidation-reduction potential in the oxidation reaction of chlorine ion as expressed in the formula (2) is +1.35V (potential with respect to an Ag/AgCl reference electrode), whereas the oxidation-reduction potential in oxidation reaction of water as expressed in the formula (3) is +0.682V (electric potential with respect to an Ag/AgCl reference electrode; determined from the standard oxidation-reduction potential, where pH=6.3). The oxidation-reduction potential in the oxidation reaction of chlorine ion is thus higher than that in the oxidation reaction of water. In other words, the oxidation reaction of chlorine ion is less likely to be induced thermodynamically. Note, however, that both of the reactions can be induced thermodynamically in a case where an oxidation-reduction potential is +2V. In this case, the oxidation reaction rate of oxidation reaction of chlorine ion is higher than that of oxidation reaction of water. It is evident from the fact that an exchange current density of oxidation reaction of chlorine ion is generally higher than that of oxidation reaction of water.

As described above, it was confirmed that a substance, such as chlorine ion, whose exchange current density is higher than that of the oxidation reaction of water, even if the substance has an oxidation-reduction potential higher than that of water, is effectively used as an acid-generating assistant agent. It was also confirmed that not only a substance which generates hydrogen ions H⁺ from an acid-generating assistant agent or from water reacted with an acid-generating assistant agent, but also a substance which generates hydrogen ions H⁺ by further reaction of a product with water which product is obtained by the substance itself being oxidized, is effectively used as an acid-generating assistant agent for making faster the speed at which the glass substrate is dissolved. Namely, a substance, which causes hydrogen ions H⁺ to be indirectly generated, can be used as an acid-generating assistant agent.

Note, however, that, in a case where sodium chloride is used as an acid-generating assistant agent, Cl₂ adversely generated as expressed in the formula (2) can become bubbles and can be attached to the surface of the glass substrate 6. In view of the circumstances, it is more preferable that a substance such as sodium sulfite is used as an acid-generating assistant agent, because all products to be produced by oxidation of the acid-generating assistant agent are dissolved in the processing liquid 8.

### Embodiment 2

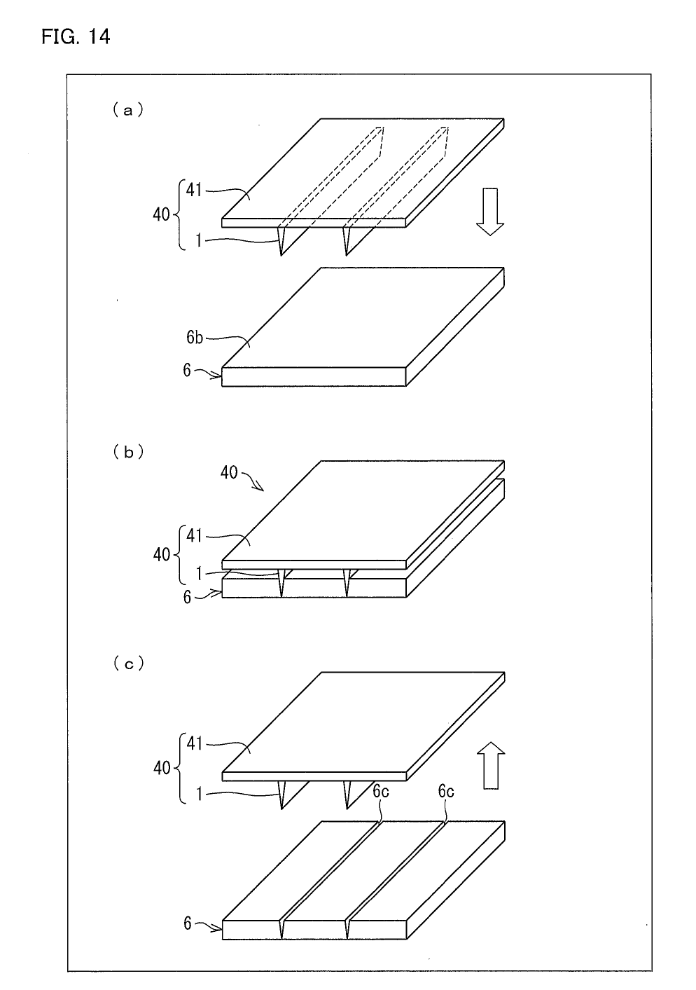

The following description will discuss Embodiment 2 of the present invention with reference to FIG. 13 and (a) through (c) of FIG. 14. For convenience, the same reference numerals are given to the members having the same functions as those of the members of Embodiment 1 and their descriptions are omitted.

FIG. 13 is a cross sectional view of an example of an electrode-supported substrate including processing electrodes used in a method for processing glass of the present embodiment. (a) through (c) of FIG. 14 illustrate, in an order in which steps are processed, a method for simultaneously forming a plurality of grooves 6c on a glass substrate 6 by using, as processing tools, an electrode-supported substrate including blade-shaped processing electrodes.

Embodiment 2 will describe a method for processing a glass with the use of an electrode-supported substrate 40 in which a plurality of the processing electrodes 1 are fixed onto a substrate 41 for supporting electrodes. The electrode-supported substrate 40 illustrated in FIG. 13 has a configuration in which the processing electrodes 1 are provided on the substrate 41 for supporting electrodes, for example, so as to be in parallel to each other. Note, however, that the number of the processing electrodes 1 is not a specific one and therefore can be one (1) or three or more. Also note that the processing electrodes 1 do not have to be provided so as to be parallel to each other.

The processing electrode 1 can be rod-shaped as illustrated in FIG. 13 or can be blade-shaped as illustrated in (a) through (c) of FIG. 14.

Dimensions of the processing electrode 1 can be suitably set, depending on the dimension of a groove 6c to be formed. Examples of the dimensions encompass (i) a height (a distance) from the surface of the substrate 41, (ii) a length, and (iii) a thickness of each blade used as the processing electrode 1.

The foregoing conductive materials can be used as a material of the processing electrode 1. For example, the processing electrode 1 can be made from a material such as platinum or iridium, as in the case of Embodiment 1. The processing electrode 1 can also be obtained by coating a blade, made from a metallic material, with a conductive material such as platinum or iridium. Alternatively, the processing electrode 1 can be obtained by coating a blade, made from an insulating material such as polymer or ceramics, with a conductive material such as platinum or iridium. Note that coating of the blade can cover the entire blade or only part near a leading end part of the blade. Alternatively, the processing electrode 1 can be obtained by (i) preparing a processing electrode made from a material such as platinum or iridium and then coating, with an insulating material such as polymer, part of the processing electrode excluding a leading end part of the processing electrode. This allows a reduction in an amount of an electric current flown in response to an applied electric potential, and ultimately allows a reduction in power consumption.

The substrate 41 is provided to mechanically support the processing electrode 1. In order to apply an electric potential to the processing electrode 1, it is necessary that the processing electrode 1 be able to be electrically connected to an electric potential control device (not illustrated). For this purpose, a connection terminal 42 is provided to the substrate 41. The connection terminal 42 is configured to electrically connect the substrate 41 to the electric potential control device. This causes the connection terminal 42 to be electrically connected to the processing electrode 1.

The dimension of the substrate 41 can be appropriately set, depending on (i) a dimension of and the number of the processing electrode 1, (ii) the distance between the processing electrodes 1, and other factors so that the substrate 41 can support the processing electrode(s) 1. Hence, the dimension of the substrate 41 is not particularly limited. Note, however, that it is possible to easily carry out positioning of the processing electrode(s) 1 to a region(s) where the groove(s) 6c is(are) to be formed, in a case where the dimension of a fixing surface of the substrate 41, onto which surface (a surface facing the glass substrate 6) the processing electrode(s) 1 is(are) fixed, is identical to that of the surface 6b, to be processed, of the glass substrate 6. Accordingly, the fixing surface of the substrate 41 preferably has the above dimension.

A concrete processing method will be described below with reference to (a) through (c) of FIG. 14.

First prepared are the electrode-supported substrate 40 and the glass substrate 6 serving as an object to be processed (see (a) of FIG. 14).

Then, the electrode-supported substrate 40 is disposed on the glass substrate 6 such that blade-shaped processing electrodes 1 are in contact with a surface 6b, to be processed, of the glass substrate 6, and then the electrode-supported substrate 40 and the glass substrate 6 are immersed in the processing liquid 8 (see FIG. 2), in a manner as early described. While the processing electrodes 1 are being in contact with the surface 6b, to be processed, of the glass substrate 6, the potential control device 5 (see FIG. 2a) electrochemically applies a positive electric potential to the processing electrodes 1. This causes the processing to start. Specifically, parts, on the glass substrate 6 with which parts the processing electrode 1 is contact, are locally dissolved. As the glass substrate 6 is dissolved and as the processing time go on, the processing electrodes 1 move in the direction of gravity due to the weight of the substrate 41 onto which the processing electrodes 1 are fixed. Note, however, that alternative configuration can be employed in which appropriate external means for moving the processing electrodes 1 are provided so that the processing electrodes 1 are moved in the direction of gravity. Then, for example, (i) after the substrate 41 reaches the surface 6b, to be processed, of the glass substrate 6 or (ii) after the application of electric potential is stopped when the grooves 6c have a desired depth (see (b) of FIG. 14), the electrode-supported substrate 40 is pulled up so as to be separated from the glass substrate 6 (see (c) of FIG. 14). In this way, a plurality of grooves 6c can be simultaneously formed on the glass substrate 6.

The description above has discussed an example in which the grooves 6c are formed on the glass substrate 6. Note, however, that the present embodiment is not limited to such an example.

For example, in the method illustrated in (a) through (c) of FIG. 14, the glass substrate 6 can be cut into pieces by forming the grooves 6c so deep as to reach the bottom surface of the glass substrate 6.

In a case where the cutting of the glass substrate 6 is carried out as the processing of the glass substrate 6, each blade-shaped processing electrode 1 are set, for example, so as to have a length of not less than a depth of the surface 6b. A height (a length) of each blade from the surface of the substrate 41 is set so as to be not less than a thickness of the glass substrate 6. Intervals at which the processing electrodes 1 can be set, depending on the size (width) of a glass piece (a glass plate) to be cut out. Processing time is adjusted to be equal to (i) a time period required for the substrate 41 to reach the surface 6b, to be processed, of the glass substrate 6 or (ii) a time period required for each of the blades to reach the bottom surface of the glass substrate 6. This allows the glass substrate 6 to be divided into a plurality of glass pieces (glass plates) each having a desired size when the electrode-supported substrate 40 is pulled up to be separated from the glass substrate 6 after the processing of the glass substrate 6.

The width of the groove 6c can be adjusted by varying the width of the blade-shaped processing electrode 1.

The blade of the processing electrode 1 can have a tapered or an inverse tapered shape. Alternatively, the processing electrode 1 can be a rod-shaped.

### Embodiment 3

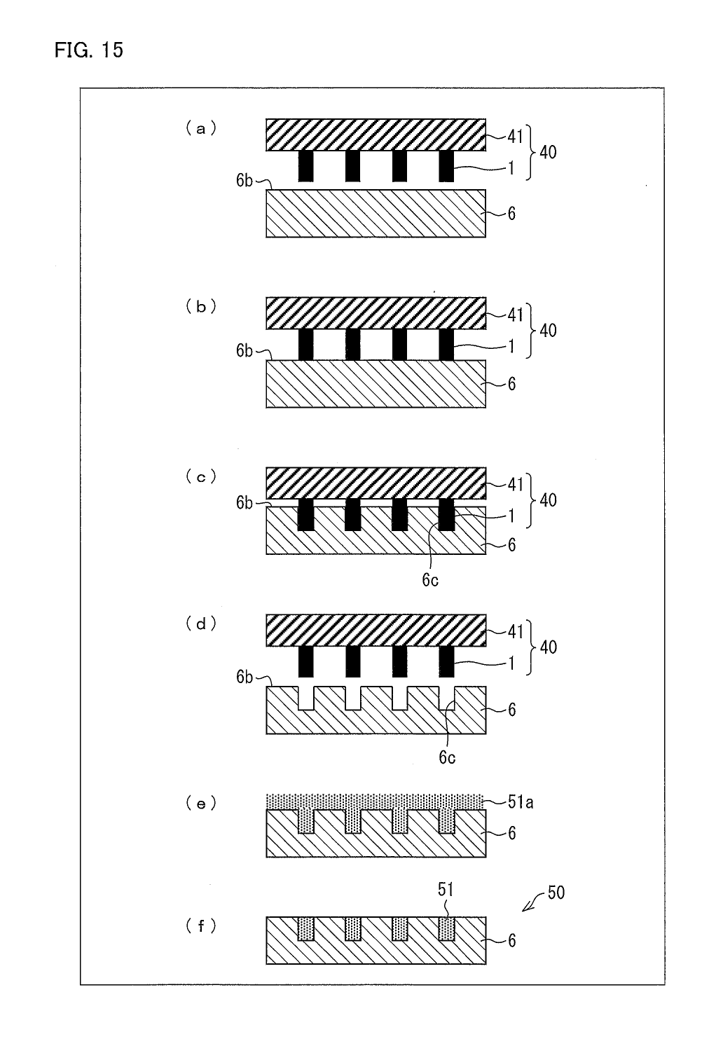

Embodiment 3 of the present invention will be described with reference to (a) through (f) of FIG. 15. Since differences will be discussed in Embodiment 3 between the present embodiment and Embodiments 1 and 2, Embodiment 3 will use the same reference numerals for the members having the same functions as those of the numerals used in Embodiments 1 and 2, and their descriptions will be omitted.

Embodiment 3 will describe a case where a buried wiring board, in which buried wires are formed in a glass substrate 6, is produced with the use of the processing method of the present invention. For this purpose, blade-shaped electrodes are used as processing electrodes 1.

FIG. 15 illustrates, in an order in which steps are processed, a method for forming buried wires in the glass substrate 6, in cross sectional views.

As illustrated in (a) of FIG. 15, an electrode-supported substrate 40 is prepared, which supports processing electrodes 1 formed in accordance with a desired pattern of buried wires. Then, the electrode-supported substrate 40 and the glass substrate 6 are disposed so that the processing electrodes 1 are aligned in respective parts, to be processed, of the glass substrate 6.

Subsequently, as illustrated in (b) of FIG. 15, the processing electrodes 1 are immersed in the processing liquid 8 (see in FIG. 2) so as to be in contact with a surface 6b, to be processed, of the glass substrate 6. An electric potential is applied to the processing electrodes 1 while the processing electrodes 1 are being in contact with the glass substrate 6. The processing is thus started.

After the processing is started, as illustrated in (c) of FIG. 15, the glass substrate 6 is dissolved in the vicinity of the processing electrodes 1, so that grooves 6c are formed.

After the desired depth of the grooves 6c has been obtained, the application of electric potential to the processing electrodes 1 is stopped and the electrode-supported substrate 40 is pulled up (see (d) of FIG. 15). The processing thus ends.

Subsequently, as illustrated (e) of FIG. 15, a metal layer 51a for wiring is deposited on a processed surface 6b, including inside walls of the respective grooves 6c, with the use of a known method such as sputtering.

Finally, as illustrated in (f) of FIG. 15, parts of a deposited metal layer 51a for wiring are removed by use of a known chemical grinding method or a mechanical grinding method, which parts exclude the metal layer 51a for wiring deposited in the grooves 6c. In this way, the buried wires 51 are formed in the glass substrate 6. The buried wiring board 50 is thus manufactured.

According to the manufacturing method of Embodiment 3, buried wires having a desired pattern can be formed without using a resist material or the like. Accordingly, it is possible to pattern prepare buried wires at less cost than a common method employing wet etching in which photolithography is used.

### Embodiment 4

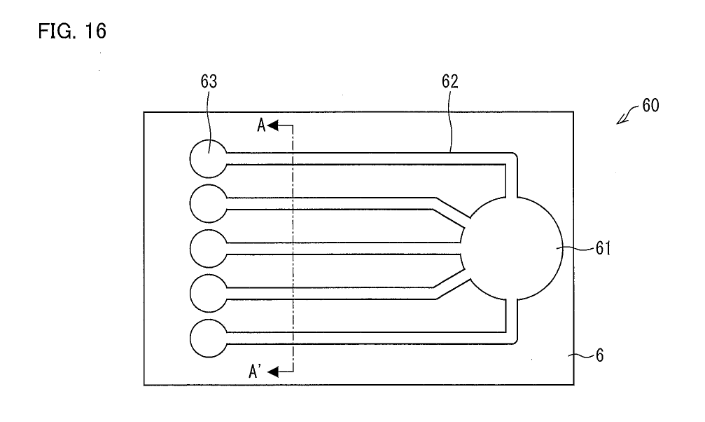

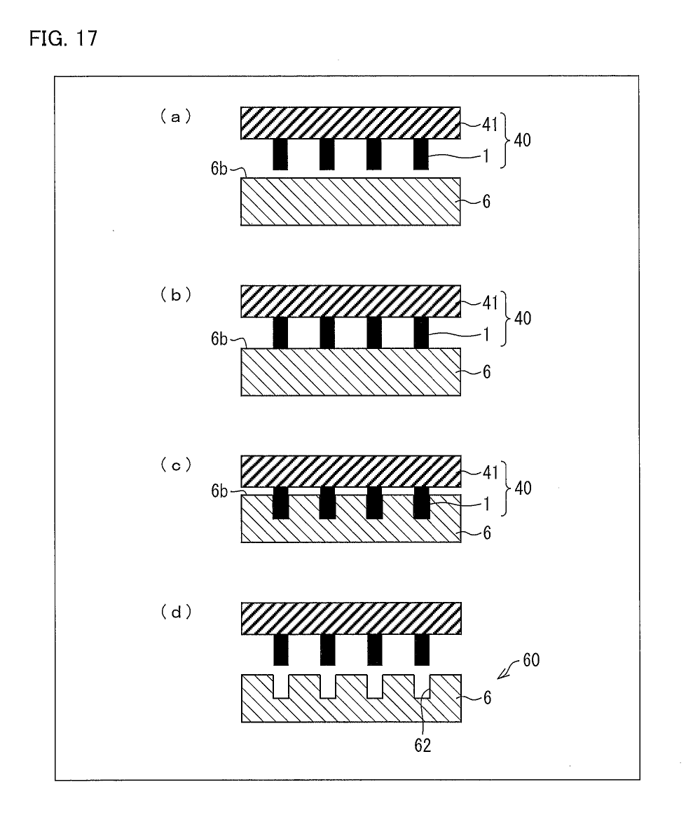

Embodiment 4 of the present invention will be described with reference to FIG. 16 and (a) through (d) of FIG. 17. Since differences will be discussed in Embodiment 4 between the present embodiment and Embodiments 1 to 3, Embodiment 4 will use the same reference numerals for the members having the same functions as those of the numerals used in Embodiments 1 to 3, and their descriptions will be omitted.

In Embodiment 4, the processing method of the present invention is used to form a pattern of a microchip used in a microchemical analysis system for analyzing a sample solution. In particular, blade-shaped electrodes are used as processing electrodes 1 in order that groove-shaped microchip solution channels of the microchip are formed with the use of the processing method.

FIG. 16 is a plan view illustrating a recess pattern of a microchip to be formed by use of the manufacturing method of Embodiment 4.

As illustrated in FIG. 16, a glass substrate 6, which is to be a main body of the microchip 60, has in its surface a reagent vessel 61 to be filled with chemicals, (i) reaction vessels 63 where a various type of the chemicals are mixed and reacted with each other and (ii) microchip solution channels (flow paths) 62 in which the chemicals move from the reagent vessel 61 to the respective reaction vessel 63.

Now, a method for forming the microchip solution channels 62 will be described below with reference to (a) through (d) of FIG. 17.

FIG. 17 illustrates, in an order in which steps are processed, a method for forming the microchip solution channels 62 in the glass substrate 6 which is to be a main body of the microchip 60, in cross sectional views. Note that (a) through (d) of FIG. 17 illustrate views corresponding to cross sectional views taken along the arrow A-A′ of the microchip 60 illustrated in FIG. 16.

As illustrated in (a) of FIG. 17, an electrode-supported substrate 40 is first prepared, which supports the processing electrodes 1 formed in accordance with a pattern of the microchip solution channels 62. Then, the electrode-supported substrate 40 and the glass substrate 6 are disposed so that the processing electrodes 1 are aligned in respective parts, to be processed, of the glass substrate 6.

Subsequently, as illustrated in (b) of FIG. 17, the processing electrodes 1 are immersed in the processing liquid 8 (see in FIG. 2) so as to be in contact with the surface 6b, to be processed, of the glass substrate 6. An electrical potential is applied to the processing electrodes 1 while the processing electrodes 1 are being in contact with the glass substrate 6. The processing is thus started.

After the processing is started, the glass substrate 6 is dissolved in the vicinity of the processing electrodes 1, so that grooves (parts of the glass substrate 6 into which parts the processing electrodes 1 fit) are formed, as illustrated in (c) of FIG. 17, the grooves being to be microchip solution channels.

After the desired depth of the grooves has been obtained, the application of electric potential to the processing electrodes 1 is stopped and the electrode-supported substrate 40 is pulled up (see (d) of FIG. 17). The processing thus ends. Consequently, the microchip solution channels 62 are formed on the glass substrate 6.

According to the manufacturing method of Embodiment 4, the microchip solution channels having a predetermined pattern can be formed without using a resist material or the like. Accordingly, it is possible to manufacture a microchip at less cost than a common method employing wet etching in which photolithography is used.

### Embodiment 5

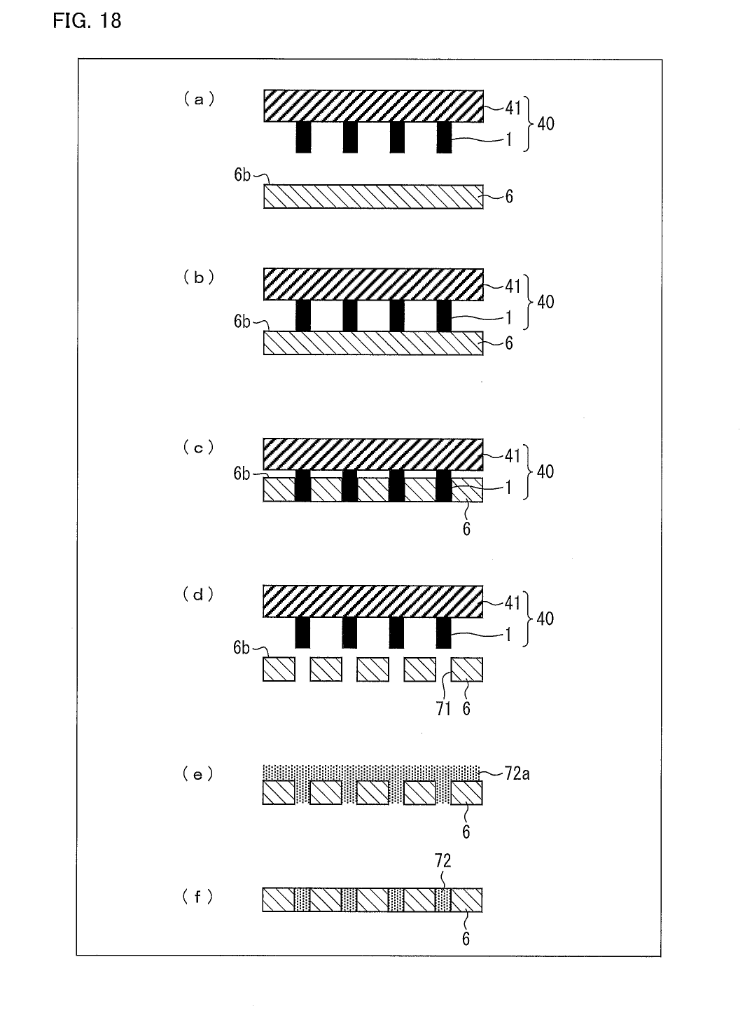

Embodiment 5 of the present invention will be described with reference to (a) through (f) of FIG. 18. Since differences will be discussed in Embodiment 5 between the present embodiment and Embodiments 1 to 4, Embodiment 5 will use the same reference numerals for the members having the same functions as those of the numerals used in Embodiments 1 to 4, and their descriptions will be omitted.

In Embodiment 5, the processing method in accordance with the present invention is used to form through-type electrodes in a glass substrate. For this purpose, rod-shaped electrodes having a length greater than the thickness of the glass substrate are used as processing electrodes 1.

FIG. 18 illustrates, in an order in which steps are processed, a method for forming through-type electrodes according to Embodiment 5, in cross sectional views.

As illustrated in (a) of FIG. 18, an electrode-supported substrate 40 is prepared, which supports the processing electrodes 1 formed in accordance with a desired pattern of the through-type electrodes. Then, the electrode-supported substrate 40 and the glass substrate 6 are disposed so that the processing electrodes 1 are aligned in respective parts, to be processed, of the glass substrate 6.

Subsequently, as illustrated in (b) of FIG. 18, the processing electrodes 1 are immersed in the processing liquid 8 (see FIG. 2) so as to be in contact with the surface 6b, to be processed, of the glass substrate 6. An electrical potential is applied to the processing electrodes 1 while the processing electrodes 1 are in contact with the glass substrate 6. The processing is thus started.

After the processing is started, the glass substrate 6 is dissolved in the vicinity of the processing electrodes 1 (see (c) of FIG. 18). After a certain processing time has passed, through-holes (parts of the glass substrate 6 into which the processing electrodes 1 fit) 71 are formed.

After the through-holes are formed, the application of electric potential to the processing electrodes 1 is stopped and the electrode-supported substrate 40 is pulled up (see (d) of FIG. 18). The processing thus ends.

Subsequently, as illustrated in (e) of FIG. 18, a metal layer 72a for electrodes is deposited on a processed surface 6b, including inside walls of the through-holes 71, with the use of a known method such as sputtering and electrolytic plating.

Finally, as illustrated in (f) of FIG. 18, parts of the deposited metal layer 72a for electrodes are removed by use of a known chemical grinding method or a mechanical grinding method, which parts exclude the metal layer 72a for electrodes deposited in the through-holes 71. In this way, the through-type electrodes 72 are formed in the glass substrate 6.

According to the manufacturing method of Embodiment 5, through-type electrodes can be formed without using a resist material or the like. Accordingly, it is possible to manufacture through-type electrodes at less cost than a common method employing wet etching in which photolithography is used.

### Embodiment 6

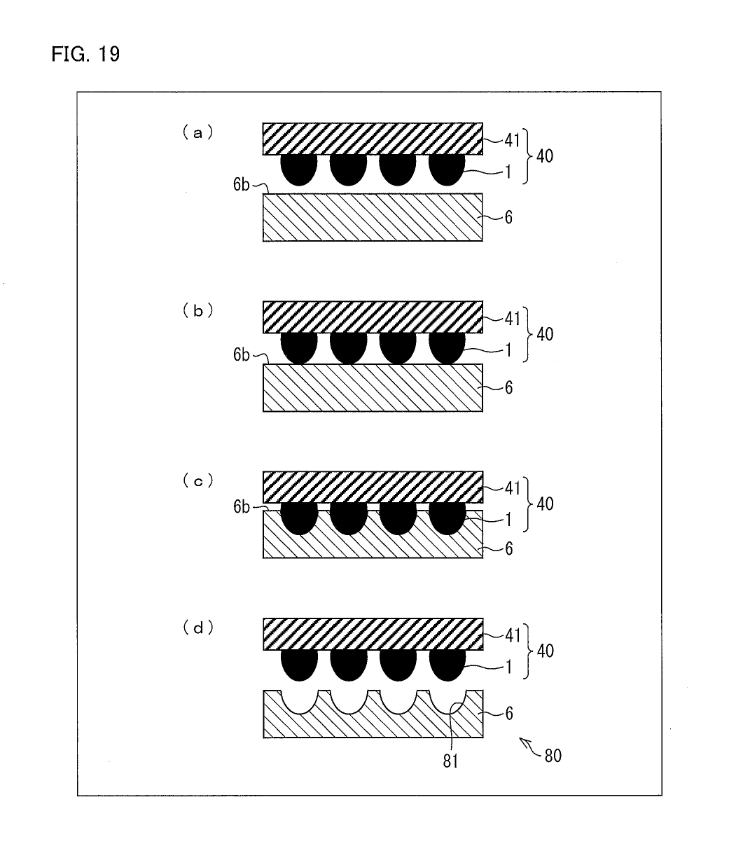

Embodiment 6 of the present invention will be described with reference to (a) through (d) of FIG. 19. Since differences will be described in Embodiment 6 between the present embodiment and Embodiments 1 to 5, Embodiment 6 will use the same reference numerals for the members having the same functions as those of the numerals used in Embodiments 1 to 5, and their descriptions will be omitted.

In Embodiment 6, the processing method in accordance with the present invention is used to form a microlens array substrate. In Embodiment 6, electrodes whose surfaces have an arc shape are used as processing electrodes 1, in order that a recess pattern of a microlens is formed.

FIG. 19 illustrates, in an order in which steps are processed, a method for manufacturing a microlens array substrate according to Embodiment 6, in cross sectional views.

As illustrated in (a) of FIG. 19, an electrode-supported substrate 40 is prepared, which supports the processing electrodes 1 formed in accordance with a target pattern of a microlens array. Then, the electrode-supported substrate 40 and the glass substrate 6 are disposed so that the processing electrodes 1 aligned in respective parts, to be processed, of the glass substrate 6.

Subsequently, as illustrated in (b) of FIG. 19, the processing electrodes 1 are immersed in the processing liquid 8 (see in FIG. 2) so as to be in contact with a surface 6b, to be processed, of the glass substrate 6. An electric potential is applied to the processing electrodes 1 while the processing electrodes 1 are being in contact with the glass substrate 6. The processing is thus started.

After the processing is started, as illustrated in (c) of FIG. 19, the glass substrate 6 is dissolved in the vicinity of the processing electrodes 1.

Finally, after the desired recess pattern (parts of the glass substrate 6 into which parts the processing electrodes 1 fit) has been obtained, the application of electric potential to the processing electrodes 1 is stopped and the electrode-supported substrate 40 is pulled up (see (d) of FIG. 19). The processing thus ends. Consequently, the microlens array substrate 80 having the recess pattern 81 for a microlens array is formed.

According to the manufacturing method of Embodiment 6, recesses for a microlens array can be formed without using a resist material or the like. Accordingly, it is possible to manufacture a microlens array substrate at less cost than a common method employing wet etching in which photolithography is used.

In the present invention, the acid-generating assistant agent may be made from a substance whose oxidation-reduction potential is lower than that of water. The acid-generating assistant agent may also be made from a substance whose exchange current density during oxidation reaction is higher than that during oxidation reaction of water. The acid-generating assistant agent may have both properties described above. That is, the above-mentioned substances may be identical.

In a case in which a substance, whose oxidation-reduction potential (that is, the oxidation-reduction potential of an acid-generating assistant agent) is lower than that of water, is used as an acid-generating assistant agent, more hydrogen ions can be generated in response to an applied electric potential which is so low that the oxidation reaction of water is difficult to be caused, as compared with in a case in which no acid-generating assistant agent is used. Accordingly, it is possible (i) to increase processing speed and (ii) to carry out a processing by applying a lower applied voltage. Therefore, the application of high voltage, which may cause the corrosion of processing tools, can be avoided.

An acid-generating assistant agent, whose exchange current density during oxidation reaction is higher than that during oxidation reaction of water, is oxidized more rapidly than water at a certain voltage. Accordingly, the substance, even if its oxidation-reduction potential is higher than that of water, can generate more hydrogen ions than that in a case in which no acid-generating assistant agent is used. This allows an increase in processing speed in response to a predetermined applied voltage.

Further, in the present invention, it is preferable that all products other than the hydrogen ions, that are generated upon being oxidized via oxidation of the acid-generating assistant agent, are dissolved in the processing solution. In other words, the acid-generating assistant agent is preferably a substance which generates, upon being oxidized, only products which are dissolved in the processing solution under the condition in which the processing method is implemented.

According to the configuration, no bubble is produced in the processing solution since all products generated via the oxidation of the acid-generating assistant agent are dissolved in the processing solution. It is thus possible to prevent the processing of glass from being inhibited by bubbles. Consequently, the processing can form a groove or a hole whose surface includes less concavity and convexity.

Further, in the present invention, the acid-generating assistant agent is preferably sulfite salt.

In a case where the acid-generating assistant agent is sulfite salt, the acid-generating assistant agent generates a large amount of hydrogen ions in response to a low applied potential, since the potential require for the oxidation reaction of sulfite salt is lower. This allows an increase in processing speed, even in a case where a low potential is applied.

Further, in the present invention, it is preferable that at least one of the processing electrode and the glass is moved, while the processing electrode and the glass are being in contact with or in proximity to each other.

By moving at least one of the processing electrode and the glass, while the processing electrode and the glass are being in contact with or in proximity to each other, at least one hole or groove having a desired dimension can be formed in the glass, or the glass can be cut.

Further, in the present invention, it is preferable that the processing electrode is disposed on the glass so as to be moved by gravitation, as the glass is dissolved.

According to the configuration, no special mechanism for moving the processing electrode is required. Therefore, the processing can be performed at a lower cost.

The method for manufacturing a wiring board in accordance with the present invention includes the steps of: forming holes or grooves for buried wires in a glass substrate by use of the method for processing glass; and forming buried wires in the respective holes or the respective grooves.

According to the above-mentioned method, the method for processing glass in accordance with the present invention is used to form the holes or grooves for buried wires in the glass substrate, so that the wiring board can rapidly be manufactured. It is thus possible to manufacture a larger number of the wiring boards at a lower cost.

The method of the present invention for manufacturing a microchip is method for manufacturing a microchip used to analyze a sample solution, the microchip including flow paths on a glass substrate, said method comprising the step of: forming the flow paths in the glass substrate by use of the above-mentioned method for processing glass.

According to the above-mentioned method, the method for processing glass in accordance with the present invention is used to form the flow paths on the glass substrate, so that the microchip can rapidly be manufactured. It is thus possible to manufacture a larger number of the microchip at a lower cost.

The method of the present invention for manufacturing a microlens array substrate is a method for manufacturing a microlens array substrate comprising the step of: forming a recess pattern of the microlens array substrate by use of the above-mentioned method for processing glass.

According to the above-mentioned method, the method for processing glass in accordance with the present invention is used to form the recess pattern of the microlens array, so that the microlens array can rapidly be manufactured. It is thus possible to manufacture a larger number of the microlens array at a lower cost.

Note that the present invention is not limited to the above-described embodiments and may be varied within the scope of the patent claims. Namely, the technical scope of the present invention encompasses other embodiments in which technical means are incorporated, which technical means are appropriately varied within the scope of the patent claims.

### INDUSTRIAL APPLICABILITY

The present invention allows glass to be processed with fewer steps and at a lower cost, as compared with conventional methods, and also allows glass to be processed very finely because it does not require a mask pattern. The present invention is therefore applicable to processing and manufacturing of products, in which the glass is used, such as (i) a glass substrate in a display device such as a liquid crystal or a plasma display, (ii) an ink-jet head in an ink-jet printer, (iii) a microchip used in a microchemical analyzing system, and a microlens array.

### REFERENCE SIGNS LIST

1 Processing electrode
2 Counter electrode
3 Reference electrode
4 Processing electrode holding tube
5 Potential control device
6 Glass substrate (Glass)
6a Hole
6b Surface
7 Fixing jig
8 Processing liquid (Processing solution)
9 Stirring bar
10 Heat insulation plate with a stirring function
11 Tank for processing liquid (Container)
20 Processing apparatus
40 Electrode-supported substrate
41 Substrate
42 Connection terminal
50 Buried wiring board (Wiring board)
51 Buried wires
51a Metal layer for wiring
60 Microchip
61 Reagent vessel
62 Solution channel (Flow paths)
63 Reaction vessel
72 Through-type electrode
72a Metal layer for electrodes
80 Microlens array substrate
81 Recess pattern

1. A method for processing glass comprising the step of:
locally dissolving a part of the glass, which part is located in the vicinity of a processing electrode, by causing the processing electrode, that acts as an anode, to be in contact with or in proximity to the glass in a processing solution, the processing solution containing fluoride ions, water, and an acid-generating assistant agent which is more easily oxidized than water and generates hydrogen ions upon being oxidized.

2. The method as set forth in claim 1, wherein:
the acid-generating assistant agent is made from a substance whose oxidation-reduction potential is lower than that of water.

3. The method as set forth in claim 1, wherein:
the acid-generating assistant agent is made from a substance whose exchange current density during oxidation reaction is higher than that during oxidation reaction of water.

4. The method as set forth in claim 1, wherein:
all products other than the hydrogen ions, that are generated upon being oxidized via oxidation of the acid-generating assistant agent, are dissolved in the processing solution.

5. The method as set forth in claim 1, wherein:
the acid-generating assistant agent is sulfite salt.

6. The method as set forth in claim 1, wherein:
at least one of the processing electrode and the glass is moved, while the processing electrode and the glass are being in contact with or in proximity to each other.

7. The method as set forth in claim 1, wherein:
the processing electrode is disposed on the glass so as to be moved by gravitation, as the glass is dissolved.

8. A method for manufacturing a wiring board, comprising the steps of:
forming holes or grooves for buried wires in a glass substrate by use of a method for processing glass recited in claim 1; and
forming buried wires in the respective holes or the respective grooves.

9. A method for manufacturing a microchip used to analyze a sample solution, the microchip including flow paths on a glass substrate,
said method comprising the step of:
forming the flow paths in the glass substrate by use of a method for processing glass recited in claim 1.

10. A method for manufacturing a microlens array substrate comprising the step of:
forming a recess pattern of the microlens array substrate by use of a method for processing glass recited in claim 1.
